(19) United States
(12) Patent Application Publication
(10) Pub. No.: US 2007/0096725 A1
(43) Pub. Date: May 3, 2007

(54) Measurement method and measurement apparatus for measuring recording magnetic field strength distribution of magnetic head, and manufacturing method for manufacturing the magnetic head

(75) Inventor: Akihiro Inomata, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/360,998

(22) Filed: Feb. 24, 2006

(30) Foreign Application Priority Data
Oct. 28, 2005 (JP) 2005-315233

(51) Int. Cl. G01R 33/12

(52) U.S. Cl. 324/210

(57) ABSTRACT

A method for measuring a recording magnetic field strength distribution of a magnetic head is disclosed. The method includes: a first step of setting the magnetic head to a predetermined skew angle, and magnetically forming a track on a measurement magnetic recording medium using the magnetic head in a state in which the measurement magnetic recording medium is heated to a predetermined temperature; a second step of measuring a track profile of the track by a magnetic field detection element; a third step of repeating the first step and the second step in which temperatures for heating the measurement magnetic recording medium in repeating the first step are different with each other; and a fourth step of converting track profiles obtained in the third step into a recording magnetic field strength distribution.

### BACKGROUND OF THE INVENTION

1. Field of the Invention

The present relates to a measurement method and a measurement apparatus for measuring a recording magnetic field strength distribution of a magnetic head, and a manufacturing method for manufacturing the magnetic head.

2. Description of the Related Art

As recording density of a magnetic recording apparatus increases, a signal-to-noise ratio (S/N ratio) of a magnetic recording medium is being improved and long term stability of recorded information is also being improved. In addition, as the recording density increases, various technological innovations are accelerated also for the magnetic head for recording and reproducing data to/from the magnetic recording medium. As to a reproduction element, a magnetoresistive (MR) element having a spin valve structure, or a tunnel magnetoresistive (TMR) element is adopted to achieve a high-power and a high S/N ratio. In addition, as to the recording element, it is required to generate a recording magnetic field having a sharp and large magnetic field strength in a narrow region in order to perform recording in a track width no grater than 200 nm on a magnetic recording medium having high coercivity. Such recording element is designed with an aid of a computer calculating strength distribution of the recording magnetic field.

However, although a desired recording magnetic field strength distribution is obtained by the magnetic field calculation, there may be a case in which an actually manufactured magnetic head does not show desired recording characteristics. For example, so-called off-track erase occurs in which, when recording is repeatedly performed in a track, demagnetization occurs in an adjacent track. In addition, there is a case in which an adequate output power and non-linear transition shift (NKTS) characteristics are not obtained for a desired recording density. The reasons are occurrence of an abnormal magnetic field due to manufacturing variation of magnetic heads, change of the magnetic field strength distribution due to magnetization of the magnetic recording medium and the like. In these cases, actual measurement for the recording magnetic field of the magnetic head becomes necessary.

As a method for directly measuring the recording magnetic field of the magnetic head, a method using a phenomenon that an electron beam is biased by the recording magnetic field is proposed (refer to the patent document 1, for example). Since the method requires expensive and large-scale equipment, the method cannot be used easily, and it is difficult to introduce the equipment for checking in a process of manufacturing the magnetic head due to the high cost.

In addition, a method is proposed for using a thin-film displaying a magneto-optical effect as a magnetic field detection element and measuring a magnetic field strength applied to the thin-film by measuring a polarization angle of a light passed through the thin-film (refer to the patent document 2, for example). In addition, a method is proposed in which a magnetic head performs recording to a magnetic recording medium whose saturated recording magnetic field is known so that the recording magnetic field strength of the magnetic head is indirectly measured based on relationship between recording current and saturated magnetic field (refer to the patent document 3, for example).

[Japanese Laid-Open Patent Application No. 3-138581]

[Japanese Laid-Open Patent Application No. 2000-180522]

[Japanese Laid-Open Patent Application No. 5-128448]

### SUMMARY OF THE INVENTION

An object of the present invention is to provide a new and useful method and apparatus for measuring the recording magnetic field strength distribution of the magnetic head, and to provide a method for manufacturing the magnetic head.

The object is achieved by a method for measuring a recording magnetic field strength distribution of a magnetic head, the method including:

a first step of setting the magnetic head to a predetermined skew angle, and magnetically forming a track on a measurement magnetic recording medium using the magnetic head in a state in which the measurement magnetic recording medium is heated to a predetermined temperature;

a second step of measuring a track profile of the track by a magnetic field detection element;

a third step of repeating the first step and the second step in which temperatures for heating the measurement magnetic recording medium in repeating the first step are different with each other; and

a fourth step of converting track profiles obtained in the third step into a recording magnetic field strength distribution.

According to the present invention, the measurement magnetic recording medium is heated to various temperatures so as to increase or decrease coercivity of the measurement magnetic recording medium, and recording is performed using a magnetic head that is a measurement target in the heated state at each temperature. Track profiles corresponding to each temperature are measured by a magnetic field detection element, and the track profiles are converted into magnetic field strength based on relationship between the coercivity and the temperature of the measurement magnetic recording medium. The coercivity is changed by heating the measurement magnetic recording medium. Therefore, since the coercivity is high at room temperature, a measurement magnetic recording medium that is good for thermal stability can be used. Since thermal stability of residual magnetization is high, in other words, since variation with time of reproduction outputs is small, the track profile can be measured accurately. In addition, since recording is performed in a state in which the coercivity is decreased by heating the measurement magnetic recording medium, a recording magnetic field of a small strength can be detected. Further, since thermal stability of the residual magnetization is good, the measurement medium may include a recording layer composed of minute crystal grains. Therefore, a high resolution track profile can be obtained. As a result, according to the present invention, a high resolution magnetic field strength distribution can be obtained with high reliability.

The track profile is obtained by plotting reproduction outputs for each position in a track width direction.

The object is also achieved by a method for measuring a recording magnetic field strength distribution of a magnetic head, the method including:

a first step of setting the magnetic head to a predetermined skew angle, and magnetically forming a track on a measurement magnetic recording medium using the magnetic head in a state in which the measurement magnetic recording medium is heated to a predetermined temperature;

a second step of measuring a track profile of the track by a magnetic field detection element;

a third step of repeating the first step and the second step in which temperatures for heating the measurement magnetic recording medium in repeating the first step are different with each other;

a fourth step of repeating the third step in which skew angles in repeating the first step are different with each other; and

a fifth step of converting track profiles obtained in the fourth step into a recording magnetic field strength distribution.

According to the present invention, since recording is performed by setting various skew angles for the magnetic head of the measurement target, the magnetic field strength distribution can be measured more precisely.

The object is also achieved by a method for manufacturing a magnetic head, the method including an inspection process, the inspection process including:

a first step of setting the magnetic head to a predetermined skew angle, and magnetically forming a track on a measurement magnetic recording medium using the magnetic head in a state in which the measurement magnetic recording medium is heated to a predetermined temperature;

a second step of measuring a track profile of the track by a magnetic field detection element;

a third step of identifying a position at which a recording magnetic field equal to or greater than coercivity of the measurement magnetic recording medium at the predetermined temperature is generated; and

a fourth step of comparing the position at which the recording magnetic field is generated or a recording magnetic field strength at the position with a predetermined range, and determining the magnetic head to be an conforming item when the position or the recording magnetic field strength falls within the predetermined range.

According to the present invention, in the inspection process in the manufacturing method of the magnetic head, the skew angle of the magnetic head is set to a predetermined skew angle and recording is performed in a state the measurement magnetic recording medium is heated to a predetermined temperature so that the track profile is obtained. The track profile indicates a position at which a recording magnetic field having a strength equal to or greater than the coercivity of the measurement magnetic recording medium at a temperature at which recording is preformed is generated. By comparing the obtained track profile with the reference track profile to determine whether the magnetic field strength is within a predetermined range or whether the position is within a predetermined range, information of an abnormal magnetic field strength or occurrence of recording magnetic field at an abnormal position can be obtained. Thus, it becomes possible to determine conforming items and nonconforming items of the magnetic head.

The object is also achieved by a measurement apparatus for measuring a recording magnetic field strength distribution of a magnetic head, including:

a magnetic head position determination unit;

a heating unit configured to heat a measurement magnetic recording medium;

a recording unit configured to form a track on the measurement magnetic recording medium using the magnetic head in a state in which the measurement magnetic recording medium is heated to a predetermined temperature by the heating unit;

a track profile measurement unit configured to measure a track profile of the track using a magnetic field detection element; and

a calculation unit configured to identify a position at which a recording magnetic field equal to or greater than a coercivity of the measurement magnetic recording medium at the predetermined temperature is generated. According to the present invention, a measurement apparatus applicable for the above-mentioned measurement method can be realized.

According to the present invention, a new and useful method and apparatus for measuring the recording magnetic field strength distribution of the magnetic head can be provided, and a method for manufacturing the magnetic head can be provided.

### BRIEF DESCRIPTION OF THE DRAWINGS

Other objects, features and advantages of the present invention will become more apparent from the following detailed description when read in conjunction with the accompanying drawings, in which:

FIG. 1 is a schematic block diagram of a measurement apparatus for measuring a magnetic field strength distribution of a magnetic head according to a first embodiment of the present invention;

FIG. 2 is a perspective view of the magnetic head;

FIG. 3 is a substantial part configuration diagram of a surface of a head slider of the magnetic head shown in FIG. 2 wherein the surface is opposite to the medium;

FIG. 4 is a flow diagram showing a method for measuring the magnetic field strength distribution of the magnetic head according to the first embodiment of the present invention;

FIG. 5 is a figure for explaining recording processing (1) in the first embodiment;

FIG. 6 shows relationship between the coercivity and the temperature of the measurement medium;

FIG. 7 is a figure for explaining recording processing (2) in the first embodiment;

FIG. 8 is a figure for explaining track profile measurement processing;

FIG. 9A shows a track profile recorded at a temperature T₂;

FIG. 9B shows a track profile recorded at a temperature T₃;

FIG. 9C shows a track profile recorded at a temperature T₈;

FIG. 9D shows a track profile recorded at a temperature T₉;

FIG. 10 shows relationship between reproduction output values and temperatures;

FIG. 11 shows the recording magnetic field strength distribution of the magnetic head in the recording element width direction;

FIG. 12 shows an example of measured track profiles;

FIG. 13 is a flowchart showing the method for measuring the magnetic field strength distribution of the magnetic head in the second embodiment;

FIG. 14 is a figure for explaining recording processing in the second embodiment;

FIG. 15A shows a track profile recorded by setting the skew angle to −12 degrees;

FIG. 15B shows a track profile recorded by setting the skew angle to −18 degrees;

FIG. 15C shows a track profile recorded by setting the skew angle to −45 degrees;

FIG. 16 shows the magnetic field strength distribution of the magnetic head;

FIG. 17A shows a measurement example of a track profile recorded with a skew angle 0 degree;

FIG. 17B shows a measurement example of a track profile recorded with a skew angle −12 degrees;

FIG. 18 is a figure for explaining recording processing (1) in the method for measuring the magnetic field strength distribution of the magnetic head according to the third embodiment;

FIG. 19 is a figure for explaining recording processing (1) in the method for measuring the magnetic field strength distribution of the magnetic head according to the third embodiment.

### DETAILED DESCRIPTION OF THE PREFERRED EMBODIMENTS

First, the principle of the embodiment of the present invention is described. In embodiments of the present invention, for measuring the recording magnetic field strength distribution of the magnetic head (“recording magnetic field strength” may be referred to as simply “magnetic field strength” hereinafter), recording is performed by heating-up a measurement magnetic recording medium (to be simply referred to as “measurement medium” hereinafter) to various temperatures (recording operation), then, after cooling the measurement medium to about room temperature, recorded information that is a track magnetically formed in a recording layer, for example, is reproduced (read) by a magnetic field detection element (reproduction operation). In the recording operation, by heating the measurement medium, coercivity of the measurement medium is increased or decreased. If the measurement medium is not heated, the coercivity of the measurement medium is high, and as the temperature rises, the coercivity decreases. When the coercivity becomes low, the recording layer can be magnetized even by a region in the magnetic head in which the magnetic field strength is small. Therefore, after the recording magnetic field is removed and the temperature of the recording layer returns to about room temperature, residual magnetization is formed in the recording layer. This can be reproduced by the magnetic field detection element. That is, in embodiments of the present invention, the magnetic field strength distribution of the magnetic head is measured based on relationship between the temperature and the coercivity when recording is performed by heating-up the measurement medium and based on whether the residual magnetization is formed by the recording operation.

In the following, embodiments of the present invention are described with reference to figures.

### First Embodiment

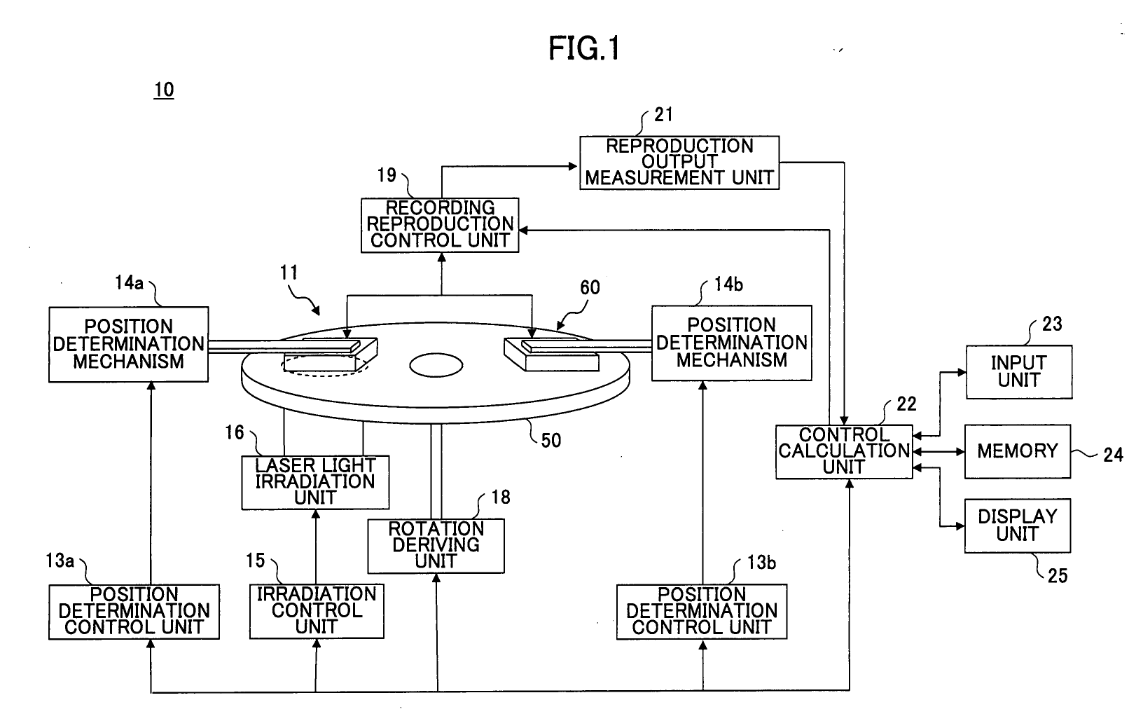

FIG. 1 is a schematic block diagram of a measurement apparatus for measuring the magnetic field strength distribution of the magnetic head of the first embodiment of the present invention.

As shown in FIG. 1, the measurement apparatus 10 for measuring the magnetic field strength distribution of the magnetic head includes a measurement medium 50, a magnetic head 11 for which the magnetic field strength distribution is to be measured, a position determination mechanism 14a, a position determination control unit 13a for the magnetic head 11, a laser light irradiation unit 16 for irradiating the measurement medium 50 with laser light, an irradiation control unit 15, a reproduction head 60 for reproducing a track profile recorded by the magnetic head 11, a position determination mechanism 14b, a position determination control unit 13b for the reproduction head 60, a recording control unit 19 for controlling recording-reproducing operations of the magnetic head 11 and the reproduction head 60, a reproduction output measurement unit 21, a rotation driving unit 18 for rotating the measurement medium 50, a control calculation unit 22 for controlling the whole of the measurement apparatus 10, an input unit 23, a memory 24, and a display unit 25 and the like.

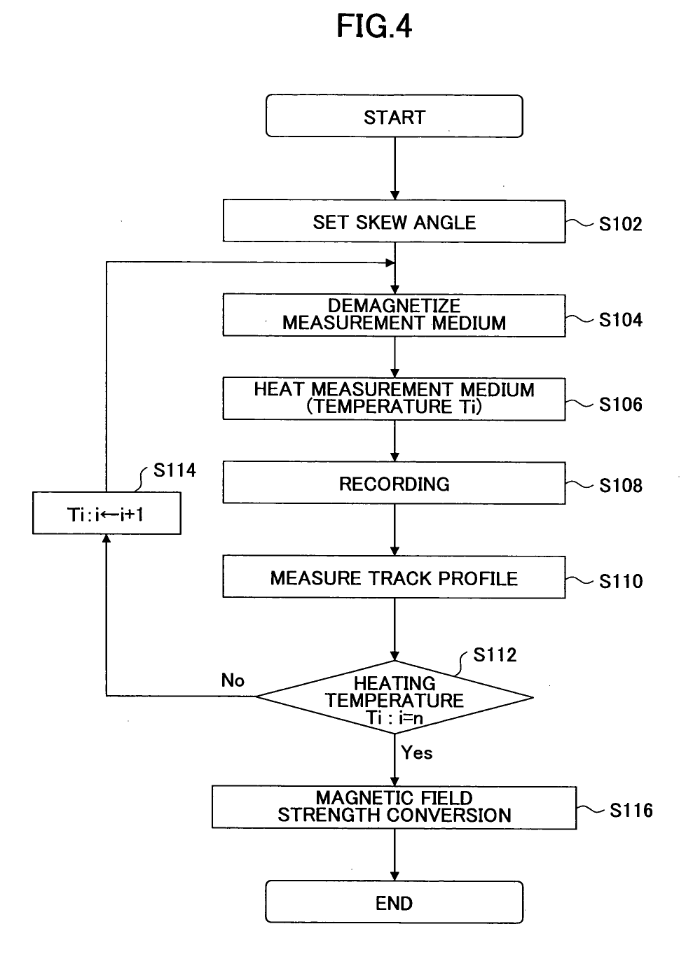

The measurement apparatus 10 operates according to a program stored in the memory 24 and to instructions input from the input unit 23 as shown in an after-mentioned flowchart of FIG. 4. First, each component of the measurement apparatus 10 is described.

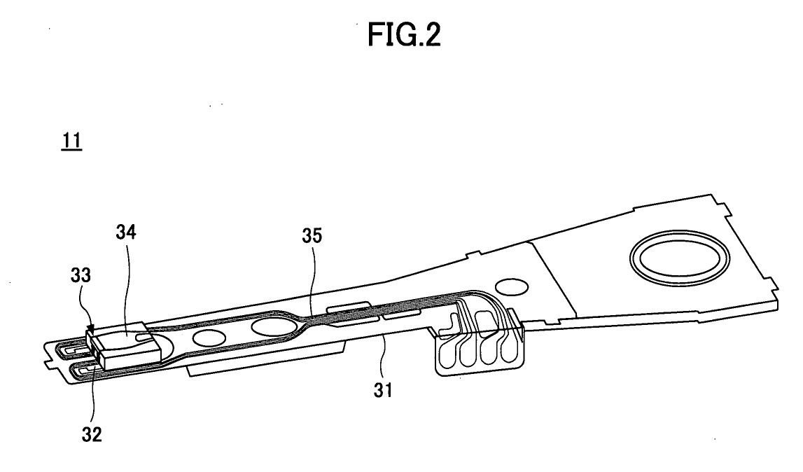

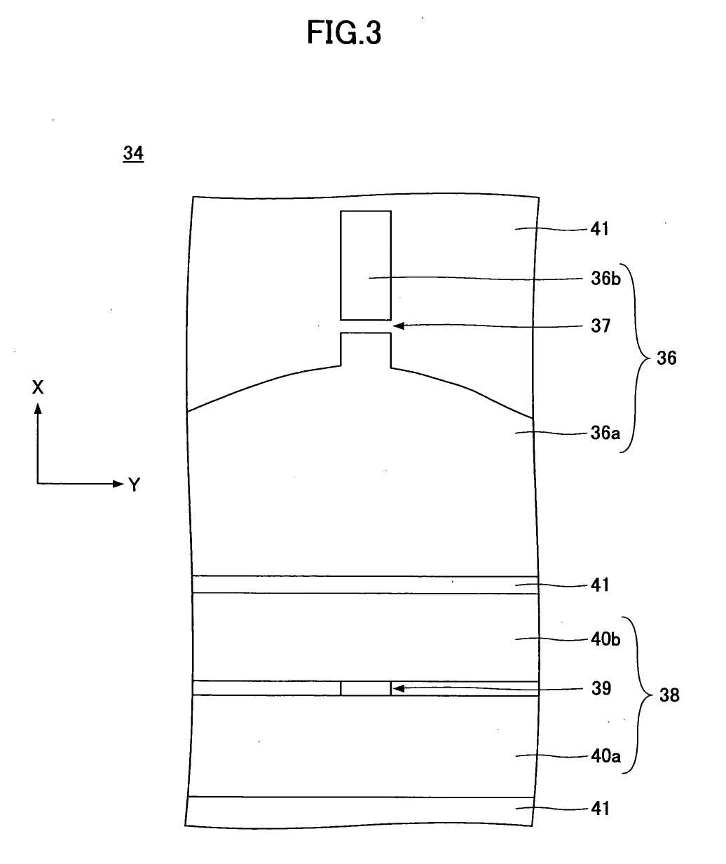

FIG. 2 is a perspective view of the magnetic head. FIG. 3 is a substantial part configuration diagram of a surface of a head slider of the magnetic head shown in FIG. 2 wherein the surface is opposite to the medium. The X axis direction shown in FIG. 3 is called as a recording element longitudinal direction, and the Y axis direction is called as a recording element width direction or simply an element width direction. The recording element longitudinal direction is parallel to a lamination direction of each layer of the recording element and the reproduction element in ordinary cases.

Referring to FIGS. 1 and 2 with FIG. 1, the magnetic head 11 roughly includes a suspension 31 formed by a plate-like metal material, a gimbal 32 attached at a top part of the suspension 31, and a head slider 34, fixed to the gimbal 32, on which a recording element 36 and a reproduction element 38 are provided. The reference number 33 indicates an element part. In addition, the suspension 31 is provided with wiring 35, for recording-reproduction signals, electrically connecting between the recording element 36/the reproduction element 38 and the recording control unit.

The base of the suspension 31 is fixed to the position determination mechanism 14a of the measurement apparatus 10. The head slider 34 floats above the measurement medium 50 by an air bearing caused between the surface of the head slider 34 opposite to the medium and the magnetic disk surface by rotating the measurement medium 50.

As shown in FIG. 3, an element part of the magnetic head 11 includes the recording element 36 and the reproduction element 38. The reproduction element 38 includes a lower shield layer 40a and an upper shield layer 40b that are composed of soft magnetic material, and a magnetoresistive film 39 sandwiched between the lower shield layer 40a and the upper shield layer 40b. The magnetoresistive film 39 detects an applied magnetic field and converts it to an electrical signal. The magnetoresistive film 39 is formed by a CIP type or CPP type spin valve film, a TMR film or the like, for example. By the way, the production element is not indispensable for the magnetic head 11.

The recording element 36 includes a lower magnetic pole 36a and an upper magnetic pole 36b that are composed of a FeCo alloy, a NiFe allow and the like, for example, and a recording gap part 37 that is sandwiched between the lower magnetic pole 36a and the upper magnetic pole 36b and that is composed of an alumina film. The lower magnetic pole 36a and the upper magnetic pole 36b are magnetically connected via a yoke (not shown in the figure) composed of soft magnetic material in the depth direction of the surface opposite to the medium. In addition, a recording coil (not shown in the figure) wound around the yoke is provided. By applying a recording current on the recording coil, a recording magnetic field is leaked from or drawn into the lower magnetic pole 36a and the upper magnetic pole 36b, so that the recording magnetic field is generated from the surface of the recording gap part 37 in the measurement medium side. In addition that the alumina film 41 forms the recording gap 37, the alumina film 41 is formed under the lower shield 40a and between the upper shield 40b and the lower magnetic pole 36a, and the alumina film 41 is formed such that it covers the lower magnetic pole 36a and the upper magnetic pole 36b.

The reproduction head 60 shown in FIG. 1 has a structure almost the same as that of the above-mentioned magnetic head. However, the recording element is not essential for the reproduction head 60. The reproduction head 60 may include only the reproduction element. It is preferable that a width of the magnetoresistive film of the reproduction head 60 (length of the magnetoresistive film in the Y axis direction shown in FIG. 3) is smaller than a width of the recording element 36 of the magnetic head 11. Accordingly, the reproduced output can be measured with higher resolution when measuring an after-mentioned track profile, so that the magnetic field strength distribution can be measured in more detail.

The position determination mechanisms 14a and the position determination control unit 13a hold the magnetic head 11, and the position determination mechanism 14b and the position determination control unit 13b hold the reproduction head 60. In addition, the position determination mechanisms and the position determination control units control a radial position (track position) of the head on the measurement medium 50.

Position control for the magnetic head 11 and the reproduction head 60 may be performed by recording track servo information on the measurement medium 50 beforehand. Each of the magnetic head 11 and the reproduction head 60 reproduces the track servo information, so that the control calculation unit 22 and the position determination control units 13a and 13b control positions based on a track servo signal provided via the recording reproduction control unit 19. Accordingly, the positions of the magnetic head 11 and the reproduction head 60 can be controlled more accurately, so that track position determination can be performed with high precision. Accordingly, a more accurate and precise track profile can be obtained.

Although not shown in the figure, the laser light irradiation unit 16 includes a light source such as a semiconductor laser, a condenser, a position determination mechanism, a focus servo mechanism and the like. The laser irradiation unit 16 receives a driving current corresponding to an output power and track position information of the magnetic head 11 from the control calculation unit 22 via the irradiation control unit 15, and irradiates a region around a recording position of the measurement medium with laser light.

In addition, as shown in FIG. 1, the laser light irradiation unit 16 is placed in an opposite side of the measurement medium 50 with respect to the magnetic head 11. This is because spatial limitation is small in this arrangement. As described later, by using a transparent material as a substrate of the measurement medium 50, the recording layer of the measurement medium 50 can be efficiently heated.

It is needless to say that the laser light irradiation unit 16 can be placed such that it directly heats the recording region of the measurement medium from the magnetic head side although this placement is disadvantageous in view of spatial limitation. According to this placement, heating can be performed more efficiently. In this case, a region before a recording position in the measurement medium 50 with respect to the rotation direction may be irradiated with the laser light.

The recording reproduction control unit 19 converts a recording signal of a predetermined recording frequency into a recording current and supplies the current to the recording coil of the magnetic head 11 based on an instruction of the control calculation unit 22 so that the magnetic head 11 performs recording operation for the measurement medium 50. In addition, the recording reproduction control unit 19 sends a reproduction signal, that forms the track profile, obtained by the reproduction head 60 to the reproduction output measurement unit 21.

The reproduction output measurement unit 21 detects peak values of the reproduced signal, and performs A/D conversion on the value, and sends the converted signal to the control calculation unit 22 as digital data.

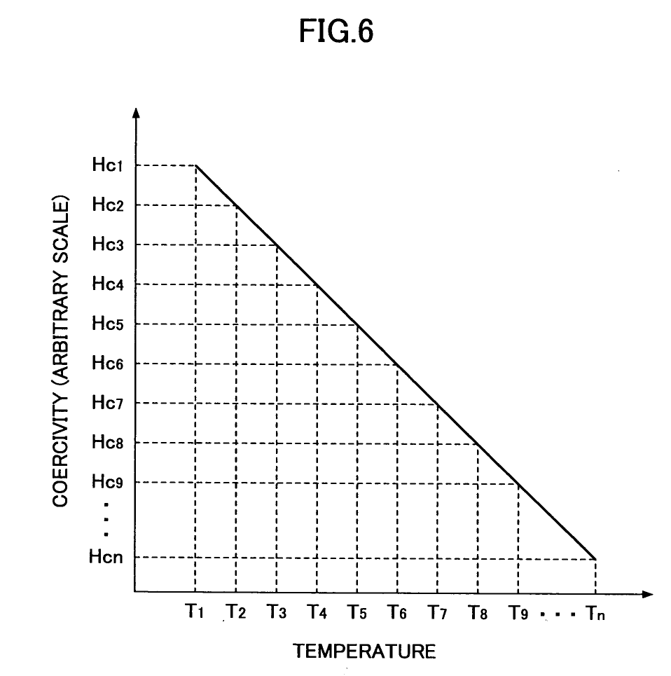

The control calculation unit 22 stores both of the obtained track profile, that is, reproduced output data and corresponding head position information in a memory. In addition, the control calculation unit 22 converts the track profile into a magnetic field strength of the magnetic head based on relationship between the-coercivity and the temperature of the measurement medium 50 that is stored in the memory 24 beforehand (the relationship is shown in after-mentioned FIG. 6). Further, the control calculation unit 22 stores the magnetic field strength of the magnetic head into a memory such as a RAM, a hard disk device, an optical disk device and the like, and displays the magnetic field strength on a display unit.

Next, a method for measuring the magnetic field strength distribution of the magnetic head using the measurement apparatus 10 is described.

FIG. 4 is a flowchart showing a method for measuring the magnetic field strength distribution of the magnetic head in the first embodiment of the present invention. The method for measuring the magnetic field strength distribution of the magnetic head is described with reference to FIG. 4.

First, the magnetic head 11 for which the magnetic field strength distribution is to be measured is attached to the position determination mechanism 14a of the measurement apparatus 10, and a skew angle of the magnetic head 11 is set in step S102. The skew angle is an angle between the magnetic element longitudinal direction of the magnetic element 36 of the magnetic head 11 and a movement direction (recording direction) of the measurement medium 50, and the skew angle is an angle in a virtual plane that is parallel to the substrate plane of the measurement medium. This definition of the skew angle also applies to the reproduction head 60.

In the first embodiment, it is assumed that the skew angle is set to be 0 degree. By the way, setting of the skew angle can be performed directly from the input unit 23 or can be performed by a program stored in the memory. In this step, the heating temperature is set to be T₁(Ti:i=1).

Next, the measurement medium 50 is demagnetized so that no track remains in the recording layer in step S104. It is preferable to perform the demagnetization in a range greater than a region on which a track is to be recorded. The method of demagnetization may be direct-current demagnetization or alternating-current demagnetization. In addition, the method may be thermal demagnetization if this method does not damage the recording layer. When the direct-current demagnetization is performed, the measurement medium 50 is attached to the rotation driving unit 18 so that a direct-current magnetic field is applied to the recording layer by the magnetic head 11. However, when track servo information is recorded on the measurement medium 50 beforehand, the direct-current magnetic field is turned off on a region on which the track servo information is recorded.

Next, the measurement medium 50 is set on the measurement apparatus 10 to rotate the measurement medium 50 at a predetermined rotation speed, and the magnetic head 11 is loaded on the measurement medium 50. In addition, the measurement medium 50 is irradiated with laser light so that the temperature of the recording layer is set to T₁ in step S106.

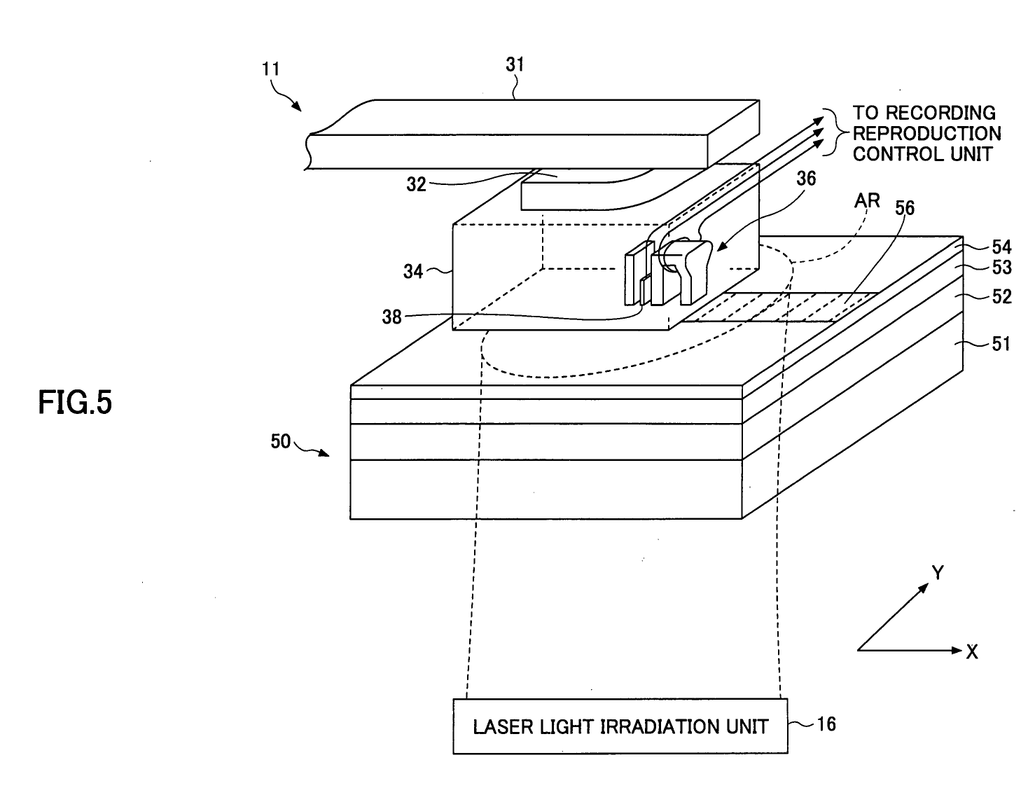

FIG. 5 is a figure for explaining recording processing in the first embodiment. As shown in FIG. 5, a foundation layer 52, a recording layer 53 and a protective film 54 are laminated on a substrate 51 to form the measurement medium 50.

The measurement medium 50 may be a so-called longitudinal magnetic recording medium in which the axis of easy magnetization of the recording layer is almost parallel to the substrate plane, a so-called perpendicular magnetic recording medium in which the axis of easy magnetization of the recording layer is almost perpendicular to the substrate plane or a so-called tilted magnetic recording medium in which an angle of the axis of easy magnetization of the recording layer with respect to the substrate plane is greater than 0 degree and is less than 90 degrees. A measurement medium 50 is selected from the above-mentioned magnetic recording media according to a target direction for measurement among directions of the recording magnetic field of the magnetic head 11 (parallel to the substrate plane, perpendicular to the substrate plane, or skew, for example). In the first embodiment, it is assumed that a magnetic field strength in which the direction of the magnetic field is parallel to the substrate surface of the magnetic head 11 (so called horizontal magnetic field strength) is measured, and that the measurement medium 50 in this embodiment is the longitudinal magnetic recording medium.

It is preferable that the substrate 51 is a transparent substrate such as a grass substrate. Since the laser light passes through the transparent substrate when heating the recording layer 53 by irradiating it with the laser light, the foundation layer 52 is irradiated with the laser light. Therefore, temperature rising speed for the recording layer 53 increases.

In addition, an orientational control film such as a NiP film may be further provided on the surface of the substrate 51, and a so-called texture that is streak projections and depressions may be formed along the recording direction on the surface of the substrate 51 or on the surface of the orientation control film. Accordingly, the axis of easy magnetization of the recording layer 53 is oriented in the recording direction so that the recording layer 53 having uniaxial anisotropy is formed. As a result, since fluctuations of the axis of easy magnetization of the recording layer 53 become small, a track profile having higher resolution can be obtained.

The foundation layer 52 is composed of Cr or Cr alloy or the like, for example (CrMo, or CrV, for example). In addition, although a known ferromagnetic material can be used as the recording layer 23, it is desirable that the recording layer 23 is composed of a ferromagnetic material such as CoPt, CoCrPt, CoCrPtB and the like that include Co and Pt. Accordingly, even when crystal grain of the recording layer 23 is miniaturized, for example, even when an average grain diameter of the crystal grain is set to be equal to or less than 10 nm, it can be retarded that residual magnetization decreases while performing measurement since thermal stability of residual magnetization is good.

In addition, the recording layer 53 may have a structure that includes two magnetic layers each being composed of a ferromagnetic material, and a non-magnetic bonding layer composed of Ru, for example, between the two magnetic layers wherein the two magnetic layers are coupled in an antiferromagnetic manner. This recording layer 53 is more preferable since the thermal stability of residual magnetization is further improved.

In addition, the recording layer 23 may be a recording layer of a so-called Granular structure that is composed of ferromagnetic crystal grain and a non-magnetic material (SiO₂, for example) surrounding the crystal grain. Also in this case, it is desirable that the ferromagnetic material is one that includes Co and Pt since magnetic anisotropy is large and thermal stability is good as mentioned above. In this case, it is preferable to use Ru or an Ru alloy that is predominantly composed of Ru between the foundation layer and the recording layer. Since zigzag noise in high recording density can be decreased, the track profile can be measured with higher resolution.

As to the protective film 54, a known material such as a carbon film or hydrogenated carbon can be used. Further, although not shown in the figure, a lubricating layer may be formed on the protective film 54.

As to the measurement medium 50, relationship between the coercivity and the temperature is obtained beforehand.

FIG. 6 shows the relationship between the coercivity and the temperature of the measurement medium. FIG. 6 shows the relationship schematically. For obtaining FIG. 6, each coercivity (Hc₁˜Hcₙ)for each of temperatures T₁˜Tₙ (T₁<T₂<. . . <Tₙ) to which the measurement medium 50 is heated up is measured by a vibration sample type magnetometer (VSM). That is, when the temperature of the measurement medium 50 is T₁, the coercivity is Hc₁, when the temperature of the measurement medium 50 is T₂, the coercivity is Hc₂, . . . , when the temperature of the measurement medium 50 is Tₙ, the coercivity is Hcₙ. The higher the temperature is, the lower the coercivity of the measurement medium 50 tends to be. This is due to the property of the ferromagnetic material. In other words, this is because, as the heating temperature rises, the temperature comes close to Curie point at which magnetic properties are transformed from ferromagnetism to paramagnetism. It is preferable that the relationship between the coercivity and the temperature of the measurement medium 50 is linear. By having such relationship, it becomes easy to convert the track profile to the magnetic field strength. Further, it becomes easy to represent the magnetic field strength distribution at equal intervals. In these points, it is preferable that the recording layer is composed of CoCrPtB.

It is preferable that the temperature T₁ that is the lowest in the measurement region is set to be room temperature, that is, 25° C. for example since the structure of the measurement apparatus can be simplified. In this case, it is not necessary to perform irradiation with the laser light to obtain T₁. It is needless to say that a cooling means for cooling the measurement medium 50 can be provided to the measurement apparatus 10 so as to set the temperature T₁ to be equal to or less than the room temperature.

The coercivity of the recording layer 53 at 25° C. is selected according to an after-described processing method for converting the track profile into the magnetic field strength. But, it is desirable to set the coercivity of the recording layer 53 at 25° C. to be greater than the maximum magnetic field strength of the magnetic head. Accordingly, the maximum magnetic field strength of the magnetic head can be measured with reliability. The coercivity of the recording layer 53 at 25° C. is set to be equal to or greater than 10 kOe, for example.

When a frequency of a recording current supplied to the magnetic head 11 is high, for example, when recording to the measurement medium 50 is performed using a recording frequency the same as that used when the magnetic head 11 is practically used, it is preferable to use so-called dynamic coercivity instead of using the coercivity measured by the VSM, wherein the dynamic coercivity is obtained by applying, to the measurement medium, a magnetic field alternating at a high frequency, that is, a frequency almost the same as the recording frequency, for example. That is, instead of using the relationship between the coercivity (coercivity measured using the VSM) and the temperature shown in FIG. 6, the relationship between the dynamic coercivity and the temperature may be used. The dynamic coercivity is greater than the coercivity measured by using the VSM, and tends to increase as the frequency increases.

A region on which the recording magnetic field is applied by the magnetic head 11 is irradiated with laser light by the laser light irradiation unit 16. It is desirable that an area AR having a uniform temperature by the irradiation with the laser light is larger than the region on which the recording magnetic field is applied by the magnetic head 11. There is a case in which correction processing may be necessary when temperature difference occurs in the region on which the recording magnetic field is applied. Thus, it is desirable that an area AR having a uniform temperature is larger than the region on which the recording magnetic field is applied by the magnetic head 11 since the correction processing is not necessary. By the way, the temperature T₁can be set to be the room temperature (25° C.) so that the irradiation with the laser light is not necessary.

By the way, instead of using the relationship between the coercivity and the temperature shown in FIG. 6, relationship between the coercivity and laser output can be used by obtaining relationship between the laser outputs and the temperature. Since the relationship between the laser output and the temperature changes according to the rotation speed of the measurement medium, the relationship is obtained according to the used rotation speed.

Next, a predetermined recording current is supplied to the recording element in a state in which the measurement medium 50 is heated-up to a predetermined temperature so as to perform recording in step S108. The recording current is an alternating current having a nearly rectangular wave in which the current value alternates between positive and negative or the recording current is a direct current. When the recording current is the alternating current, a reproduced signal becomes an alternating waveform in the track profile measurement processing (S110), and the signal amplitude is to be measured. In the following, it is assumed that the recording current is the alternating current. When the recording current is the direct current, a noise track profile may be measured, or a track profile may be measured by an after-mentioned magnetic force microscope.

Although measurement of the track profile becomes easy by recording the track on a full circle of the measurement medium, the track can be shorter than the circle, and the length of the track has no limitation. This definition of the track also applies to the second to fifth embodiments.

As shown in FIG. 5, a recording current of a predetermined frequency is supplied to the coil of the recording element 36 from the recording reproduction control unit (shown as 19 in FIG. 1). A recording magnetic field is applied to the recording layer 53 from the top of the magnetic pole of the recording element 36 so that the track 56 is magnetically formed on the recording layer 53.

The recording current value is properly set according to a purpose of measurement of the magnetic field strength distribution. For example, the recording current value may be set to be a current value used when the magnetic head is actually used in a hard disk apparatus and the like. Alternatively, the recording current value may be set to be larger than a current value used when the magnetic head is actually used in a hard disk apparatus and the like in order to easily detect abnormality of the recording magnetic field distribution. However, the recording current value needs to be set to be less than a current value that may damage the magnetic head due to excessively large current.

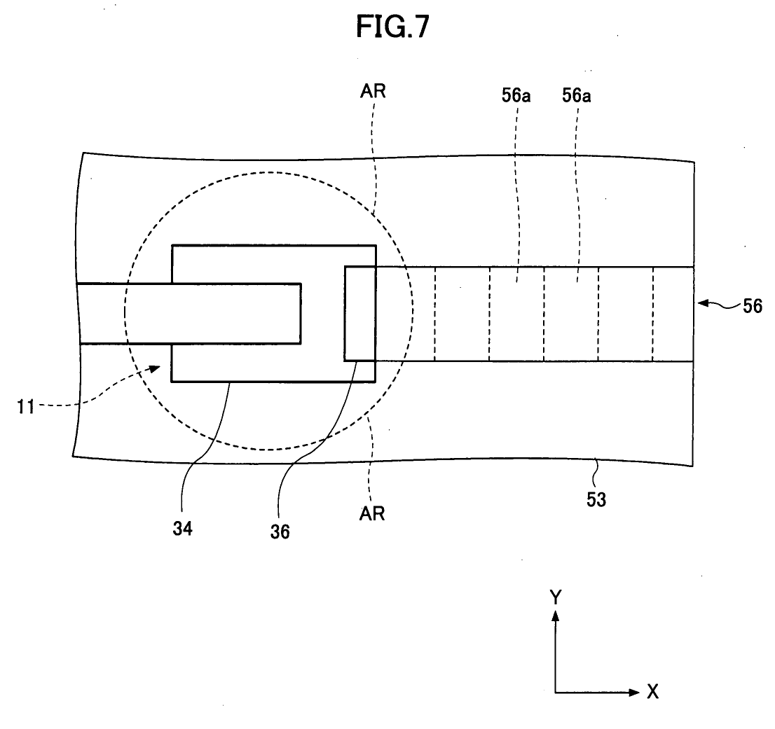

FIG. 7 is a figure for explaining the recording processing in the first embodiment. FIG. 7 is a schematic diagram, and the reproduction element of the magnetic head is not shown.

As shown in FIG. 7, a track 56 is formed along a moving direction (recording direction, X axis direction in FIG. 7) of the measurement medium by the recording element 36 of the magnetic head 11 by the recording processing. In the track 56, magnetized regions 56a each including a N-pole and a S-pole corresponding to the recording magnetic field strength distribution are formed.

In the example shown in FIG. 7, the skew angle is set to be 0 degree wherein the skew angle is an angle between the longitudinal direction of the recording element 36 and the recording direction. In addition, regions of both sides of the track 56 (track width direction, Y axis direction in FIG. 7) are in a demagnetized state.

Next, after the temperature of the recording layer 53 decreases to almost the room temperature, a reproduction output with respect to the track width direction of the track is obtained by the reproduction head 60, that is, so-called track profile is obtained in step S110.

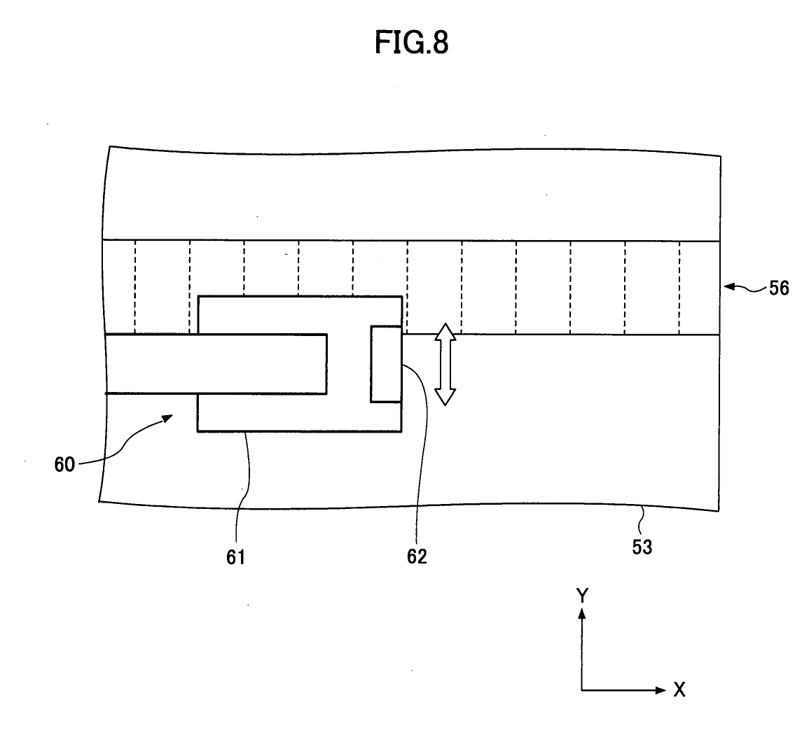

FIG. 8 is a figure for explaining track profile measurement processing. As shown in FIG. 8, for measuring the track profile, by scanning the reproduction head 60 in the track width direction (Y axis direction in FIG. 8), reproduction outputs with respect to distances from the track center in the track width direction are measured. As the reproduction outputs, signal amplitudes at a predetermined position in the track longitudinal direction (a predetermined angle from a predetermined reference position in the measurement medium 50, for example) are measured. By measuring reproduction outputs in a predetermined region along the track longitudinal direction, an average value of the reproduction outputs can be measured. In this case, measurement of the track profile is performed in the following way, for example. The reproduction outputs in the track longitudinal direction are measured by the reproduction head 60 at a position in the track width direction while the measurement medium rotates one turn, then the reproduction outputs are averaged. Next, the reproduction head is moved a little in the track width direction, and reproduction outputs are measured in the same way mentioned above. By repeating the movement and measurement so as to measure the production outputs over a region wider than a track width, the track profile can be obtained. When measuring the reproduction outputs, it is preferable to use a band-pass filter that passes only frequencies about the same as frequencies of a recorded signal in order to reduce effects of noise.

From the viewpoint of improving resolution of the track profile in the track width direction, it is preferable to use a head including a reproduction element 62 whose element width is smaller than that of the recording element 36 of the magnetic head 11.

The skew angle of the reproduction head 60 is set to be 0 degree. As described in the second embodiment, it is preferable to set the skew angle of the reproduction head to be the same as the skew angle of the magnetic head 11 since the track profile can be measured more accurately. However, the skew angle of the reproduction head 60 is not necessarily 0 degree due to constraint for attaching the position determination mechanism of the reproduction head 60 and control of floating characteristics of the reproduction head. The track profile can be measured using a reproduction element of the magnetic head 11 instead of using the reproduction head 60. Accordingly, control of the measurement apparatus can be simplified.

Next, the temperature is set to T₂that is higher than T₁ in step S114, and steps S104˜S110 are performed in the above-mentioned way. Further, the temperature Ti is set up to Tn in order and the track profile is measured in each temperature Ti in step S112.

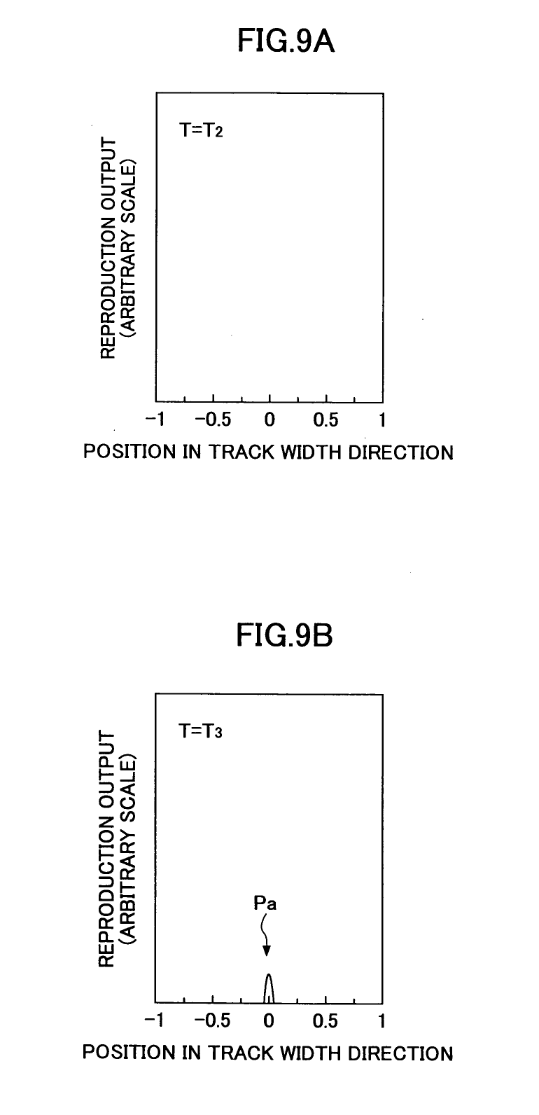

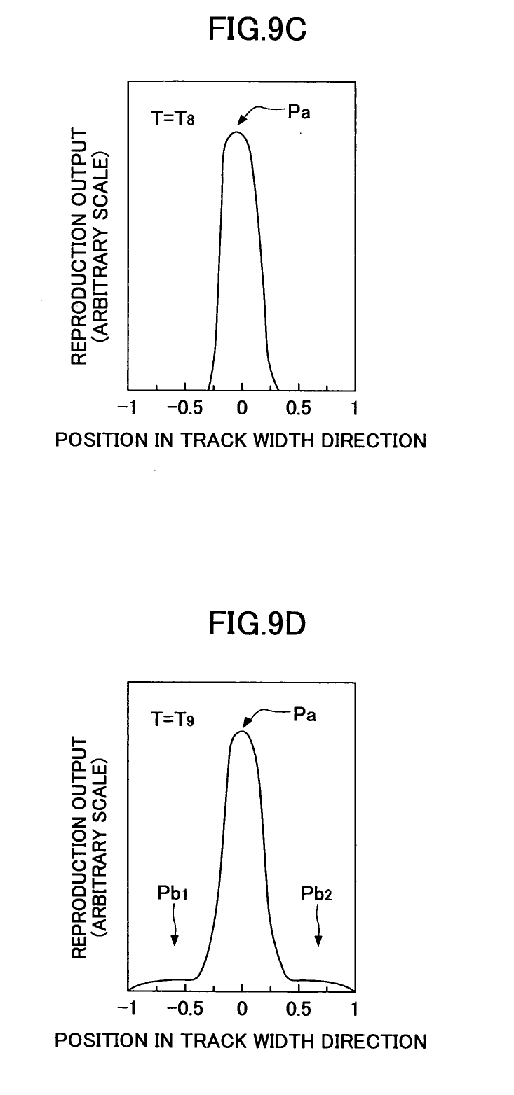

FIGS. 9A˜9D are figures showing track profiles in temperatures T₂, T₃, T₈ and T₉ (T₂<T₃<T₈<T₉). In each of FIGS. 9A˜9D, a vertical axis indicates the reproduction output, and a horizontal axis indicates a position in the track width direction (distance from the center of track, for example).

As shown in FIG. 9A, no reproduction output is obtained at the temperature T₂. This indicates that the recording layer is not magnetized since the coercivity of the measurement medium 50 at the temperature T₂is higher than the recording magnetic field strength.

Next, as shown in FIG. 9B, a profile Pa appears at the temperature T₃(next to and higher than T₂) . This indicates that a recording magnetic field strength greater than the coercivity at T₃is applied to a position at which the profile Pa appears.

Next, as shown in FIG. 9C, the profile Pa increases at the temperature T₈. The reason is that, the coercivity decreases due to the rise of the temperature of the measurement medium 50 so that the recording layer is more magnetically saturated.

Next, as shown in FIG. 9D, profiles Pb₁and Pb₂ newly appear at the temperature T₉ (next to and higher than T₈). From this phenomenon, it can be understood that each of the profiles Pb₁ and Pb₂ is almost equal to or greater than the coercivity Hc₉ at the temperature T₉ and has a magnetic field strength smaller than the coercivity Hc₈at the temperature T₈.

Next, the track profiles at the temperatures T₁˜Tₙ obtained in the above-mentioned way are converted to magnetic field strength based on the relationship between the coercivity Hc₁˜Hcₙ of the measurement medium and the temperatures T₁˜Tₙ in step S116.

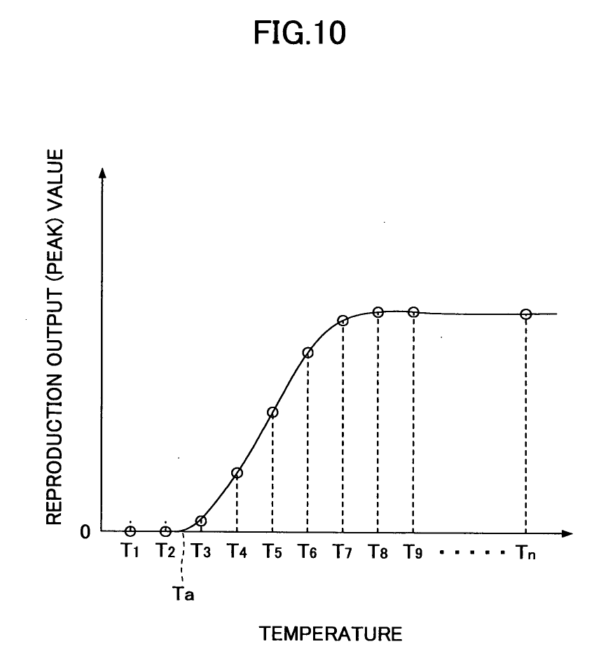

FIG. 10 shows relationship between reproduction output values and temperatures. FIG. 10 shows reproduction output values at the peak position in the track width direction of the profile Pa appearing in FIG. 9B.

As shown in FIG. 10, the reproduction output is 0 at the temperature T₂and starts to increase at the temperature T₃. This corresponds to FIG. 9A and FIG. 9B. Although it can be estimated that the profile starts to appear at the temperature Ta, the temperature T₃ at which the profile is initially observed is defined as a temperature at which the profile Pa appears. That is, it is assumed that a magnetic field strength corresponding to the coercivity of the measurement medium occurs at a position of the recording element of the magnetic head corresponding to the profile Pa. This can be generalized as follows. When a profile does not appear at a position in a track at a low temperature Ti and a profile appears at the point at a temperature Tᵢ₊₁ that is next higher than Ti, it is assumed that a magnetic field strength the same as a coercivity Hcᵢ₊₁ at Tᵢ₊₁ exists at the position of the profile. Accordingly, the track profile is converted to the magnetic field strength so that a magnetic field strength distribution can be obtained. Accordingly, the magnetic field strength distribution in the recording element width direction of the magnetic head can be obtained.

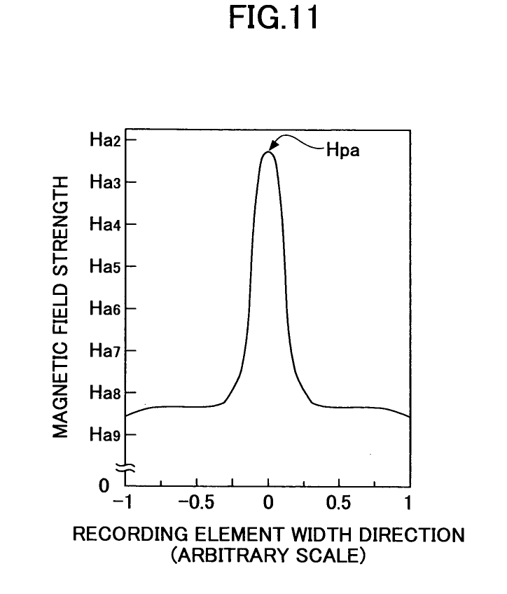

FIG. 11 shows the recording magnetic field strength distribution of the magnetic head in the recording element width direction. In FIG. 11, the vertical axis indicates the magnetic field strengths Ha₁˜Haₙ each corresponding to one of values of coercivity Hc₁˜Hcₙ. In FIG. 11, the magnetic field strengths Ha₁ and Ha₁₀˜Haₙ are not shown. The horizontal axis of FIG. 11 indicates the position in the recording element width direction, and the position of “0” indicates the center in the recording element width direction. The position in the recording element width direction is obtained by converting the position of the track profile in the track width direction.

FIG. 11 shows the magnetic field strength distribution in the recording element width direction of the magnetic head. This figure corresponds to a view obtained by viewing the magnetic field strength distribution of the magnetic head from an upstream side or a downstream side of a recording direction of the measurement medium. The peak Hpa at the position of “0” in the recording element width direction indicates a recording magnetic field strength occurring around the recording gap 37 between the lower magnetic pole 36a and the upper magnetic pole 36b. In addition, steepness of the peak Hpa, that is, the gradient of the peak Hpa is important since it relates to the degree of off-track erase.

In addition, the recording magnetic field having a magnetic field strength Ha₉ in both sides of the peak Hpa in the recording element width direction indicates a recording magnetic field strength in the vicinity of the lower magnetic pole 36a shown in FIG. 3. For example, when this magnetic field strength is relatively large, a track adjacent to a track on which recording is preformed is adversely affected in a recording operation.

Even when a region having a magnetic field strength smaller than that of the region having the large magnetic field strength exists in a position that is the same as the region having the large magnetic field strength in the recording element width direction and that is different in the recording element longitudinal direction, information indicating this fact cannot be obtained from FIG. 11. However, as mentioned above, since a magnetic field strength that actually influences to recording characteristics is the maximum magnetic field strength at each position in the recording element width direction, enough information can be obtained from FIG. 11.

In addition, since the magnetic field strength of the magnetic field strength distribution of FIG. 11 is associated with the coercivity of the measurement medium, although it is adequate for performing relative comparison, FIG. 11 may not show actual magnetic field strength. In step S116 in the flowchart shown in FIG. 4, processing for calculating a magnetic field strength distribution of real magnetic field strength can be performed. Next, first and second examples of calculation processing are described in this case.

In the first calculation processing, a reference head for which real magnetic field strength is measured beforehand is prepared. The real magnetic field strength can be measured by using the phenomenon described in the Description of the Related Art in which an electron beam is biased by a recording magnetic field. According to this measurement method, the real magnetic field strength can be measured although it is a static recording magnetic field. A recording current applied to the reference head when measuring the magnetic field using the electron beam is set to be the same as the recording current in the measurement method of FIG. 4, that is performed next.

Next, by performing the same procedure shown as S102˜S114 in FIG. 4, temperatures at which a profile appears and corresponding coercivity are measured using the reference head and a measurement medium the same as the measurement medium 50 used for the magnetic head 11. Then, based on the temperatures at which a profile appears, corresponding coercivity and the known magnetic field strength of the reference head, the magnetic field strength shown in FIG. 11 is converted to the real magnetic field strength. More specifically, relationship between the coercivity of the measurement medium at the temperature at which the profile appears and the known magnetic field strength of the reference head is obtained. Then, based on the relationship, the magnetic field strength in FIG. 11 is converted to the real magnetic field strength.

In the second calculation processing, the measurement medium is heated to each temperature (T₁˜Tₙ) and tracks (each to be referred to as “reference track”) for each temperature are formed on the measurement medium using the reference head beforehand. Each reference track is formed in a region that is not used in measurement of FIG. 4. The reference head is similar to one used in the first calculation processing, and the magnetic field strength distribution is known.

Next, when measuring the track profile (to be referred to as “measurement track profile” hereinafter) in step S110 in FIG. 4, a track profile (to be referred to as “reference track profile” hereinafter) of the reference track recorded at a temperature the same as one for a track to be measured is measured.

Next, peak strengths are compared between the measurement track profile and the reference track profile. Then, a conversion coefficient for converting the magnetic field strength (corresponding to coercivity) to the real magnetic field strength is obtained based on the peak strengths. By using the conversion coefficient, the magnetic field strength is converted to the real magnetic field strength. In this calculation processing, it is not necessary to prepare the reference tracks for every temperature T₁˜Tₙ. It is adequate to prepare reference tracks for two or more temperatures.

By using any one of the above-mentioned examples of calculation processing, the magnetic field strength distribution of the real magnetic field strength can be obtained.

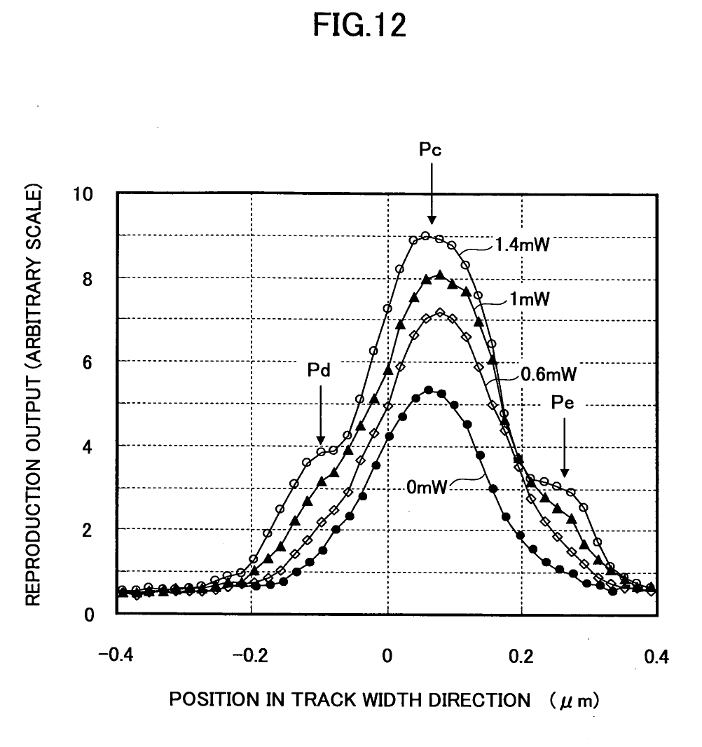

FIG. 12 shows an example of measured track profiles. FIG. 12 shows track profiles of tracks recorded by changing temperatures of the measurement medium by changing the laser output from 0 mW (no irradiation) to 1.4 mW.

As shown in FIG. 12, a main peak Pc appears in the track profile corresponding to 0 mW laser output (room temperature). When the laser output is increased to 1 mW, sub-peaks Pd and Pe start to appear in both sides of the main peak Pc. When the laser output is further increased to 1.4 mW, the sub-peaks Pd and Pe appear more clearly. In the first embodiment, coercivity of the measurement medium at the temperature at which the sub-peaks Pd and Pe appear is determined to be a magnetic field strength at a position of the recording element corresponding to the position of each of the sub-peaks Pd and Pe. Accordingly, in the first embodiment, by increasing the temperature of the measurement medium, a recording magnetic field of a relatively small magnetic field strength that cannot be detected at the room temperature can be detected.

In the measurement example in FIG. 12, the recording element width (width of the upper magnetic pole shown in FIG. 3) of the magnetic head is 250 nm, the recording current is 50 mA, the recording frequency is 1.42 MHz, and the rotation speed of the measurement medium is set to be 3000 rpm. In addition, for measuring the track profile, the reproduction element (spin-valve film) of the magnetic head that is the measurement target is used.

In the first embodiment, the measurement medium 50 is heated-up to various temperatures T₁˜Tₙ so as to change the coercivity of the measurement medium 50, and recording is performed using the magnetic head 11 that is a measurement target while changing the temperatures. Then, coercivity of the measurement medium at the lowest temperature at which residual magnetization is formed is determined to be the magnetic field strength of the recording element. By obtaining the track profile, the magnetic field strength distribution in the recording element width direction can be obtained.

According to this measurement method, the magnetic field strength distribution of the magnetic head can be measured using a simple measurement apparatus. In addition, the magnetic field strength distribution in a recording frequency to be actually used in a magnetic disk apparatus and the like can be also measured, which was impossible by the conventional technology. Therefore, since the magnetic field strength distribution can be measured in a state close to a state of real use, performance and quality of the magnetic head can be accurately determined.

It may be considered that a magnetic field strength distribution of the magnetic head can be obtained using a plurality of measurement media having various coercivity, instead of heating the measurement medium like the first embodiment, by determining whether residual magnetization is formed for each measurement medium. But, there are following superior effects according to the first embodiment.

For measuring the magnetic field strength distribution with high resolution as much as possible, it is necessary that crystal grains forming the recording layer of the measurement medium are minute. For example, for measuring the magnetic field strength distribution without heating, a measurement medium having a recording layer composed of CoCr, for example, in which the coercivity is 1 kOe at the room temperature is necessary for obtaining a magnetic field strength distribution of about 1 kOe. When the coercivity is low like this and the crystal grains are minute, stability of residual magnetization deteriorates and the residual magnetization tends to decrease as time elapses (that is, it deteriorates in thermal stability). For example, after recording, a situation may occur in which the residual magnetization decreases while detecting the residual magnetization, so that accurate measurement becomes difficult.

On the other hand, according to the measurement medium in this embodiment, thermal stability is good since the coercivity is high at the room temperature, the above-mentioned situation does not occur. Thus, by using the measurement medium having the recording layer composed of minute crystal grains, a high resolution track profile can be obtained. As a result, the magnetic field strength distribution of high resolution can be obtained.

As a modified example of the method for measuring the magnetic field strength distribution in the first embodiment, an example is explained in which concrete processing in the step S116 of magnetic field strength conversion in FIG. 4 is modified. Steps other than S116 are the same as those of the first embodiment in this modified example.

As described with reference to FIGS. 9A˜9D and 10, the coercivity corresponding to the temperature at which the profile appears is determined to be the magnetic field strength in the step s116 in the magnetic field strength conversion. On the other hand, in this modified example, a temperature at which a profile is saturated is used instead of the temperature at which the profile appears.

As shown in FIGS. 9C and 9D, as to the profile Pa, the reproduction outputs are almost the same between the temperature T₈ of FIG. 9C and the temperature T₉ of FIG. 9D. This fact is also shown in FIG. 10. The coercivity of the measurement medium at the temperature T₈ is determined to be the magnetic field strength at the profile position. Accordingly, at the temperature at which the profile is saturated, a possibility that the profile is buried in a skirt of other profile decreases so that the magnetic field can be determined more accurately.

In the first embodiment, the magnetic field strength is Ha₃ in the same profile Pa. In the modified example, it becomes Ha₈. Absolute values of Ha₃ and Ha₈ are different. But, this difference is not a problem since it is adequate that only relative strength relation is ascertained in the magnetic field strength distribution. It is needless to say that processing for calculating a magnetic field strength distribution of the real magnetic field strength (the first or the second calculation processing) can be performed like the first embodiment. In addition, in this modified example, since it is allowed that the coercivity of the measurement medium at the room temperature may be lower than that of the first embodiment, there is a merit that the range of choices for the measurement media is expanded.

In the first embodiment and the modified example, recording is performed at each temperature T₁˜Tₙ, and the track profile is measured for each temperature. But, for determining whether a recording magnetic field of a desired magnetic field strength occurs, it is adequate to measure the track profile by performing recording only at a temperature corresponding to the desired magnetic field strength. Accordingly, it can be determined whether a recording magnetic field equal to or greater than a desired magnetic field strength occurs.

### Second Embodiment

In a method for measuring the magnetic field strength distribution of the magnetic head in the second embodiment, magnetic field strength distributions are obtained by setting various skews, and the magnetic field strength distributions are synthesized so that a magnetic field strength distribution in two axis directions of the recording element width direction and the recording element longitudinal direction is obtained. In the following description, description that overlaps the first embodiment is not provided.

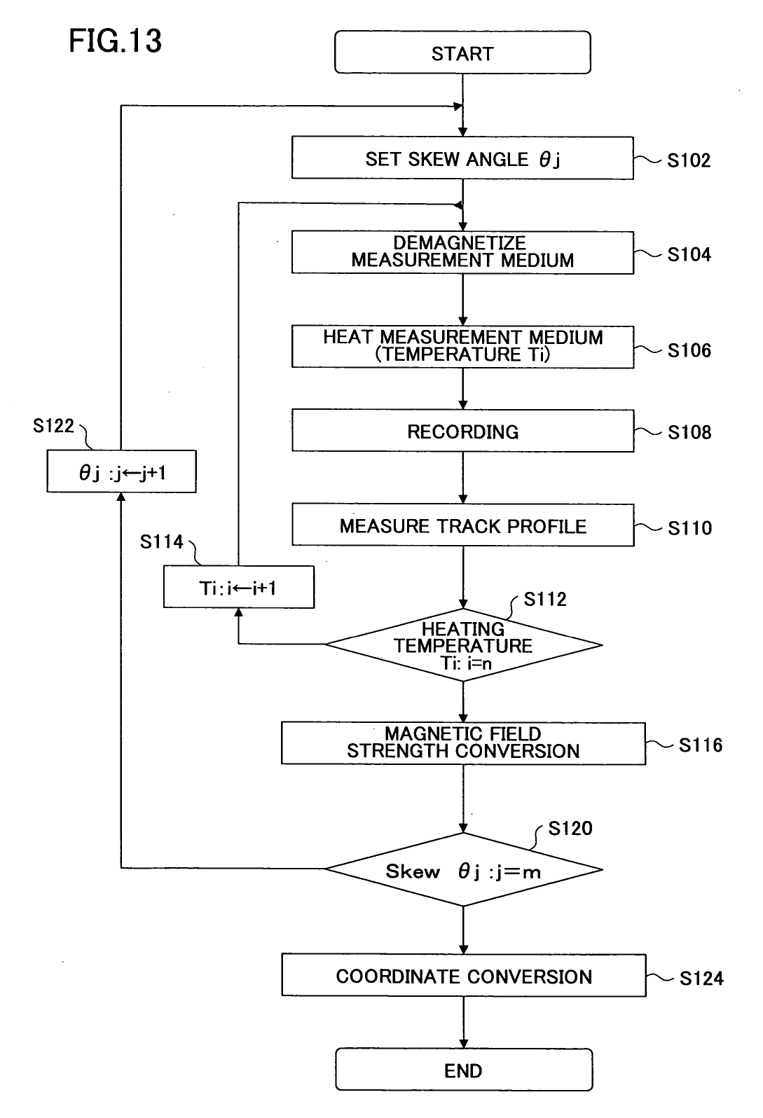

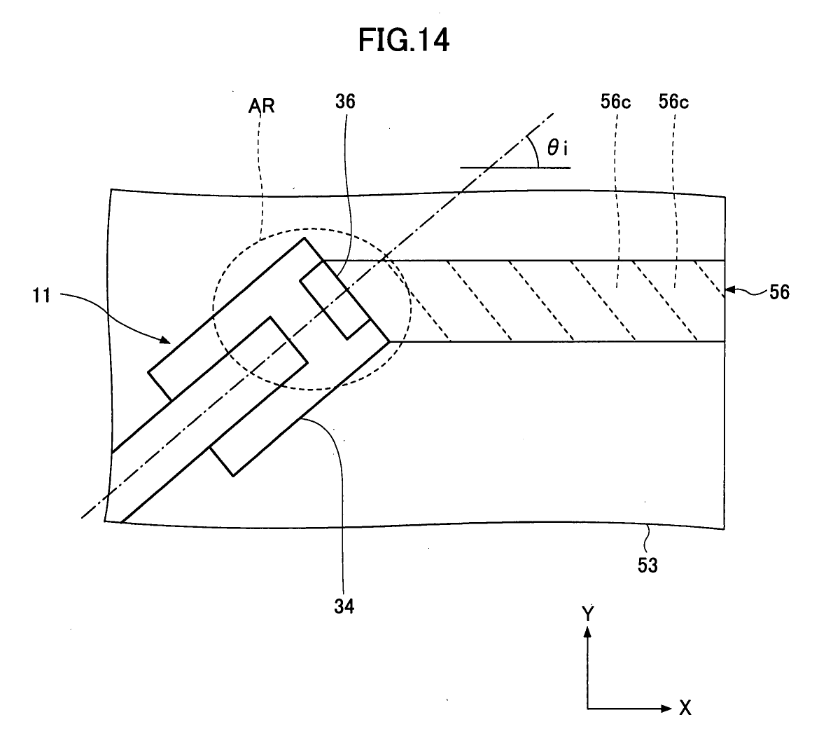

FIG. 13 is a flowchart showing the method for measuring the magnetic field strength distribution of the magnetic head in the second embodiment. FIG. 14 is a figure for explaining recording processing in the second embodiment. In the figure, the same reference numerals are assigned to corresponding parts that are described before.

As shown in FIGS. 13 and 14, first, a skew angle θj (=θ₁) of the magnetic head 11 is set in step S102. Then, the steps S104˜S114 are performed in the same way as the first embodiment, so that track profiles recorded at each of temperatures T₁˜Tₙ are obtained for the skew angle θ₁. As shown in FIG. 14, a magnetized region 56c having a shape of a parallelogram is formed on the track 56 according to the skew angle θ₁ (θⱼ).

The measurement process for the track profile is the same as one described with reference to FIG. 8. However, it is preferable that the skew angle of the reproduction head is the same as the skew angle θ₁ (θⱼ) of the magnetic head. Accordingly, more accurate measurement can be performed. By doing so, especially, when a track recording density is high, that is, when a length of the magnetization region 56c in the track longitudinal direction is short, a reproduction output waveform does not widen in the time axis direction so that accurate measurement becomes possible.

Next, track profiles are converted to magnetic field strengths based on the track profiles at temperatures T₁˜Tₙ in the skew angle θ₁, and relationship between the coercivity Hc₁˜Hcₙ of the measurement medium and the temperatures T₁˜Tₙ in step S116. As a result, the magnetic field strength distribution at the skew angle θ₁ is obtained.

Next, steps S104˜S116 are performed for each of skew angles θ₂˜θₙ. It is preferable that the range of the skew angle θ₁˜θₙ is wide as much as possible in each of the plus side skew angle and the minus side skew angle since more pieces of information for the magnetic field strength distribution can be obtained. The range of the skew angle may be in only the plus side or only the minus side. In addition, the range may or may not include 0 degree. In addition, the range may be set within ±15 degrees, for example, that is a range within which floating of the magnetic head 11 is stable.

According to the above-mentioned steps, like the first embodiment, magnetic field strength distributions of the recording element for various directions (skew angles) can be obtained.

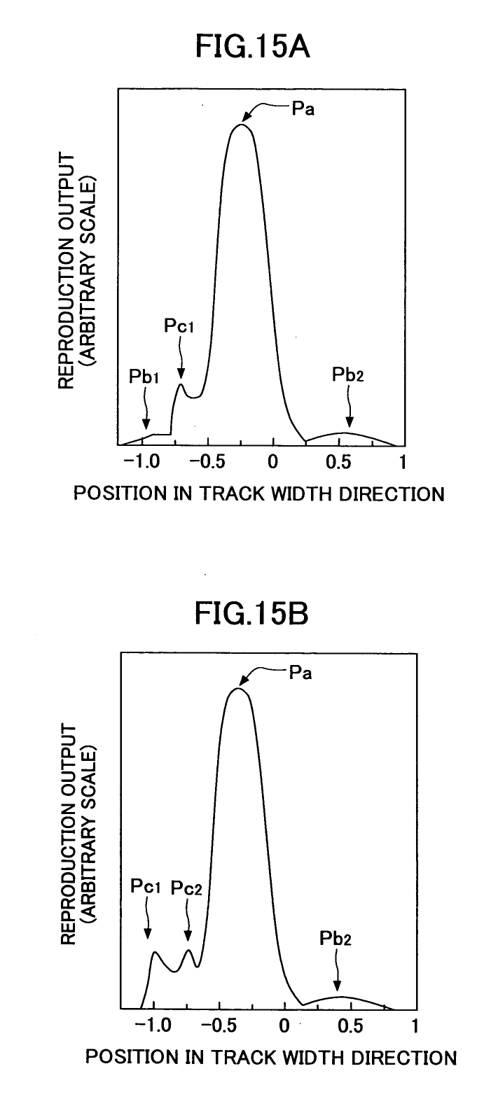

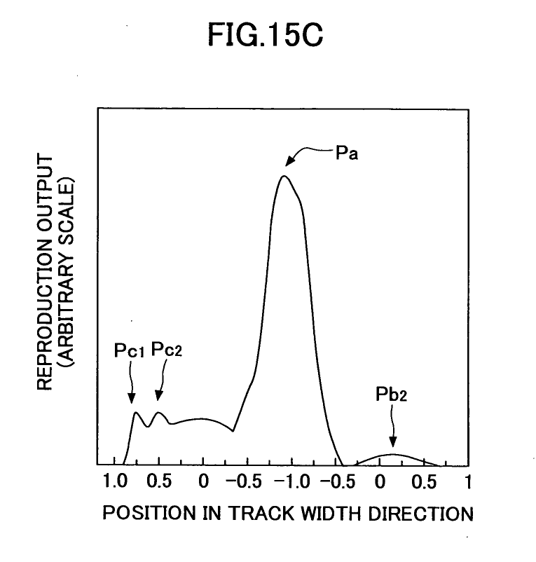

FIGS. 15A˜15C show track profiles recorded at various skew angles. The temperature at which recording is performed is the same as T₉ of FIG. 9D in the first embodiment. In each of FIGS. 15A˜15C, the vertical axis indicates reproduction outputs and the horizontal axis indicates positions in the track width direction.

As shown in FIG. 15A, when the skew angle is −12 degrees, peaks Pa, Pb₁, Pb₂ and Pc₁ are obtained. The peaks Pa, Pb₁, Pb₂ are the same as peaks Pa, Pb₁, Pb₂ appearing in the track profile when the skew angle is 0 degree as shown in FIG. 9D. The peak Pc₁appears at one of two corners of the upper magnetic pole 36b shown in FIG. 3 in a downstream side of the recording direction. Accordingly, by changing the skew angle from 0 degree, it can be understood that a peak that cannot be measured at the skew angle 0 can be measured.

As shown in FIGS. 15B and 15C, a peak Pc₂ appears in addition to the peak Pc₁ appearing in FIG. 15A. Also according to this fact, by changing the skew angle from 0 degree, it can be understood that a peak that cannot be measured at the skew angle 0 can be measured.

In FIG. 13, the magnetic field strength distributions in each skew angle are synthesized by performing coordinate conversion so as to obtain the magnetic field strength distribution for two axes of the recording element width direction and the recording element longitudinal direction in step S124.

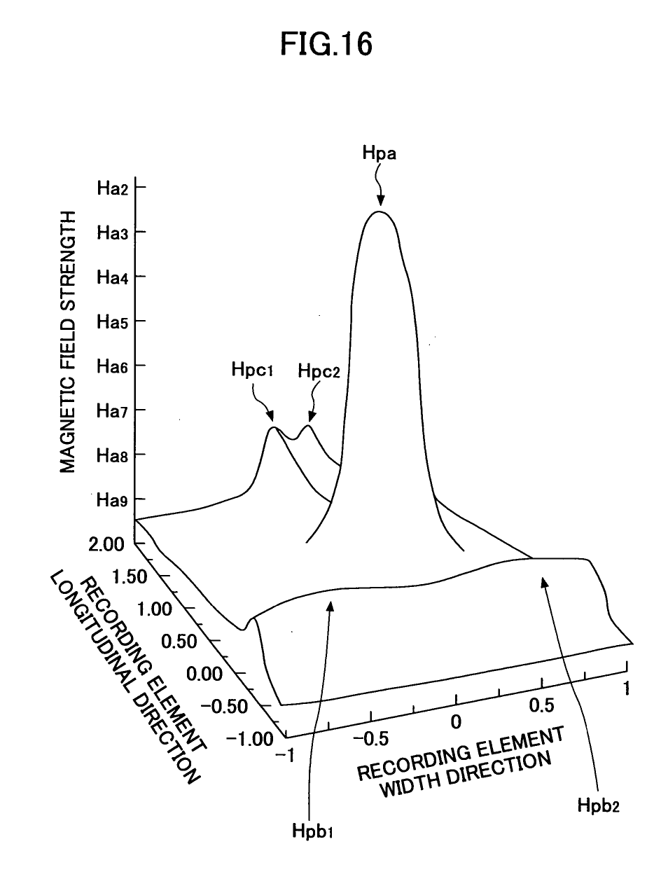

FIG. 16 shows the magnetic field strength distribution of the magnetic head. FIG. 16 is a schematic bird's-eye view obtained by viewing the distribution from the upper magnetic pole 36b side from a slanting direction.

As shown in FIG. 16, in addition to the peak Hpa at a position of the recording gap part, peaks Hpc₁ and Hpc₂ at positions of two corners of the upper magnetic pole and peaks Hpb₁ and Hpb₂ at positions of the lower magnetic pole expanding in the recording element width direction are observed. By changing a viewing angle, skirts in the downstream side of the recording direction of the peak Hpa can be observed, for example.

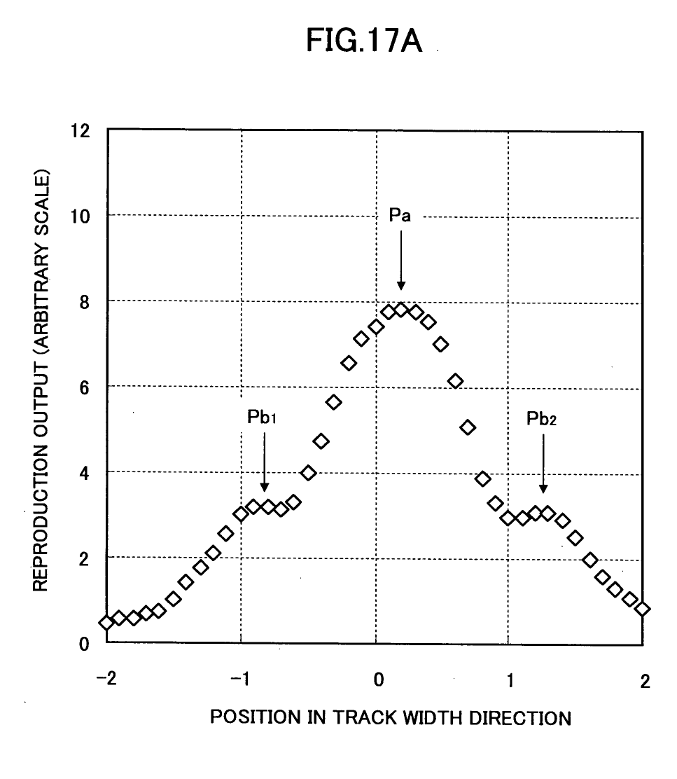

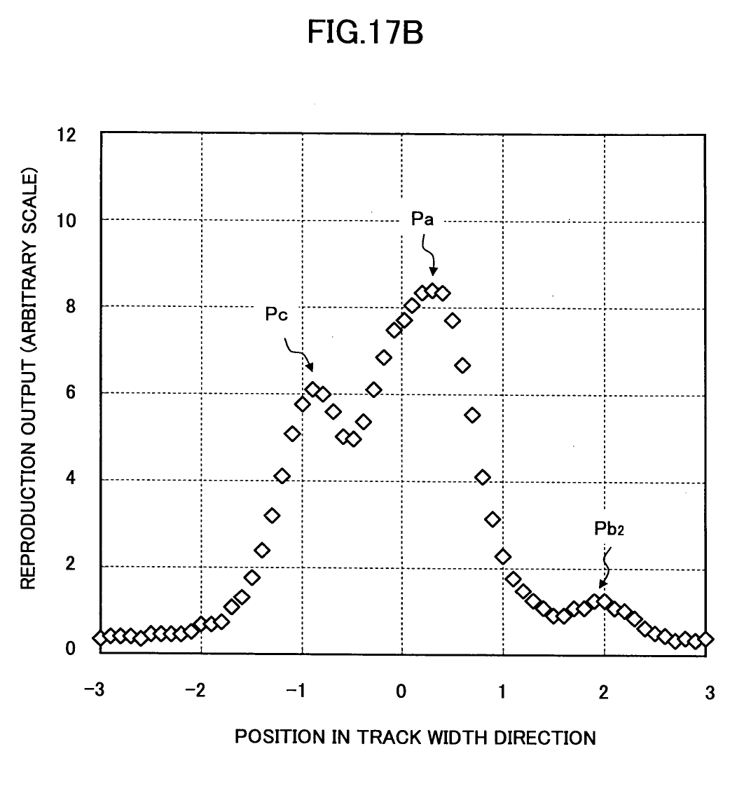

FIG. 17A shows a measurement example of a track profile recorded with a skew angle 0 degree, and FIG. 17B shows a measurement example of a track profile recorded with a skew angle −12 degrees.

FIG. 17A shows an example in which recording is performed by irradiating the measurement medium with laser light of laser output 2.6 mW using skew angle of 0 degree. In addition to the main peak Pa at the position of the recording gap part, peaks Pb₁ and Pb₂ are observed in the both sides of the main peak. In addition, as shown in FIG. 17B, when the skew angle is set to −12 degrees and the laser output condition is set to the same as FIG. 17A, a peak Pc that cannot be measured in FIG. 17A due to the existence of the main peak Pa is observed. Accordingly, by performing measurement while changing the skew angle, it can be understood that more pieces of magnetic field strength distribution information can be obtained.

The reproduction output of the peak Pb₂of FIG. 17B appears to be lower than the peak Pb₂of FIG. 17A. The reason is that an irradiation position of the laser light is shifted when performing measurement for FIG. 17B so that the temperature in the vicinity of the region corresponding to the peak Pb₂becomes lower than the temperature of the region corresponding to other peaks Pa and Pc. This is not a substantial problem of the present invention. By the way, conditions of the measurement examples shown in FIGS. 17A and 17B are the same as those of FIG. 12.

According to the second embodiment, by setting the skew angle of the magnetic head 11 of the measurement target to be various angles of plus side and/or minus side and performing measurement in the same way as the first embodiment, the magnetic field strength distribution of the whole of the recording element can be obtained. It is needless to say that the second embodiment produces effects the same as those of the first embodiment.

### Third Embodiment

The method for measuring the magnetic field strength distribution of the magnetic head in the third embodiment is the same as that of the first and second embodiments except that the magnetic head that is a measurement target and the measurement medium are different.

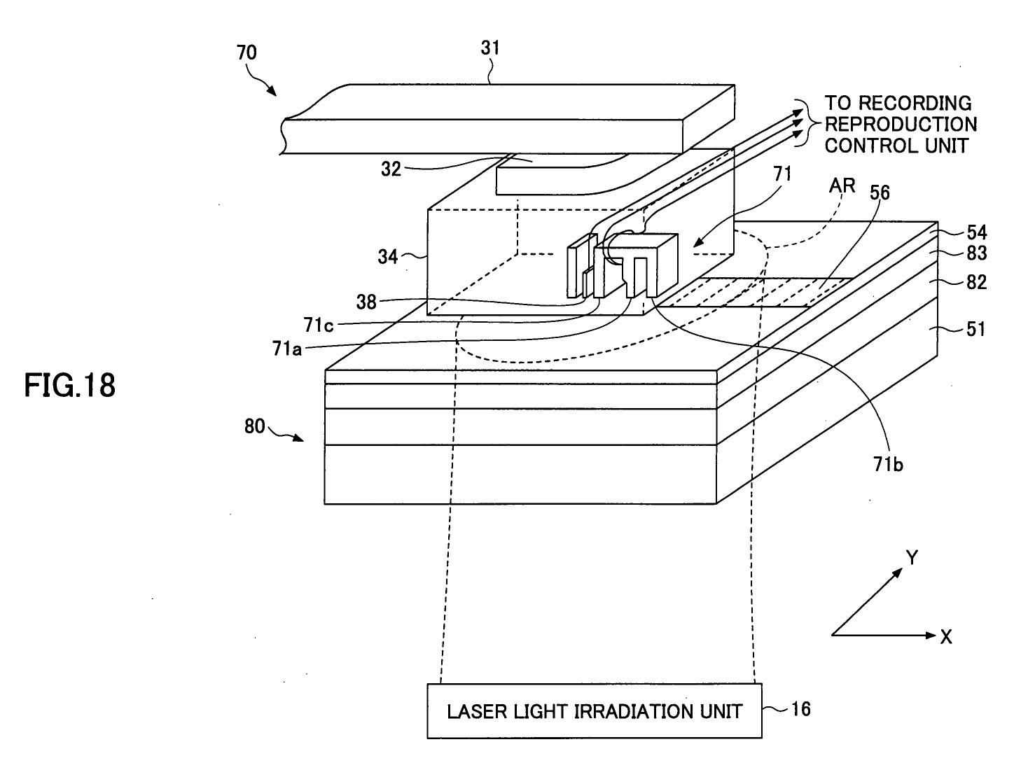

FIG. 18 is a figure for explaining recording processing in the method for measuring the magnetic field strength distribution of the magnetic head of the third embodiment. In the figure, the same reference numerals are assigned to corresponding parts that are described before.

As shown in FIG. 18, the magnetic head 70 of the target for measuring the magnetic field strength distribution is a magnetic head for perpendicular recording, and is characterized by a recording element 71. The recording element 71 includes a main magnetic pole 71a, a trailing side auxiliary magnetic pole 71b provided in a downstream side of the main magnetic pole 71a in the recording direction, a leading side auxiliary magnetic pole 71c provided in an upstream side of the main magnetic pole 71a in the recording direction, and a coil wound around a yoke connected to these magnetic poles 71a˜71c. Each of the main magnetic pole 71a, the trailing side auxiliary magnetic pole 71b, the leading side auxiliary magnetic pole 71c and the yoke is composed of a soft magnetic material, and is magnetically connected. The main magnetic pole 71a leaks or takes in a recording magnetic field having a large magnetic field strength from the top part. The trailing side auxiliary magnetic pole 71b is provided adjacent to the main magnetic pole 71a, and takes in a relatively small recording magnetic field that leaks from the periphery of the top part of the main magnetic pole 71a to prevent the magnetic field to be applied to the measurement medium 80.

A soft magnetic lining layer 82, a recording layer 83 and a protective film 54 are laminated on a substrate 51 in order to form the measurement medium 80. The soft magnetic lining layer 82 is composed of an amorphous or microcrystal soft magnetic material. As the soft magnetic material, FeSi, FeAlSi, FeTaC, CoNbZr, CoZrTa, CoCrNb, NiFe and NiFeNb can be used, for example.

The recording layer 83 is a magnetic thin film with perpendicular magnetization in which an easy axis is almost perpendicular to the substrate plane. Although the recording layer 83 may be composed of a known ferromagnetic material, it is preferable to use a ferromagnetic material, including Co and Pt, such as CoPt, CoCrPt and CoCrPtB having large magnetic anisotropy. The reason is that, by using such ferromagnetic material, thermal stability of residual magnetization is good even when crystal grains of the recording layer 83 are minute, for example, even when the average grain diameter is set to be equal to or less than 10 nm, so that it can be avoided that the residual magnetization decreases while performing measurement. The recording layer 83 may be a recording layer of a so-called Granular structure that is composed of ferromagnetic crystal grains of a ferromagnetic material and a non-magnetic material (SiO₂, for example) surrounding the crystal grains.

The recording layer 83 may be a so-called artificial lattice film in which one or more layers of Co film and Pd film are alternately laminated. Since the artificial lattice film has a large magnetic anisotropy constant, thermal stability of residual magnetization is good. The artificial lattice film is not limited to a particular structure. For example, the artificial lattice film may be a combination of Co films and Pt films.

In the third embodiment, the magnetic field strength distribution of the magnetic head 70 for perpendicular magnetic recording is measured according to a method similar to the measurement method of the first embodiment shown in FIG. 4, or the measurement method of the second embodiment shown in FIG. 13. In the following, the measurement method of the third embodiment is described with reference to the flowchart of FIG. 4.

First, the skew angle of the magnetic head 70 that is the measurement object is set to an angle in a range similar to the first or second embodiment in step S102. The skew angle may be set to 90 degree. In the following, an example in which the skew angle is set to 90 degrees is described.

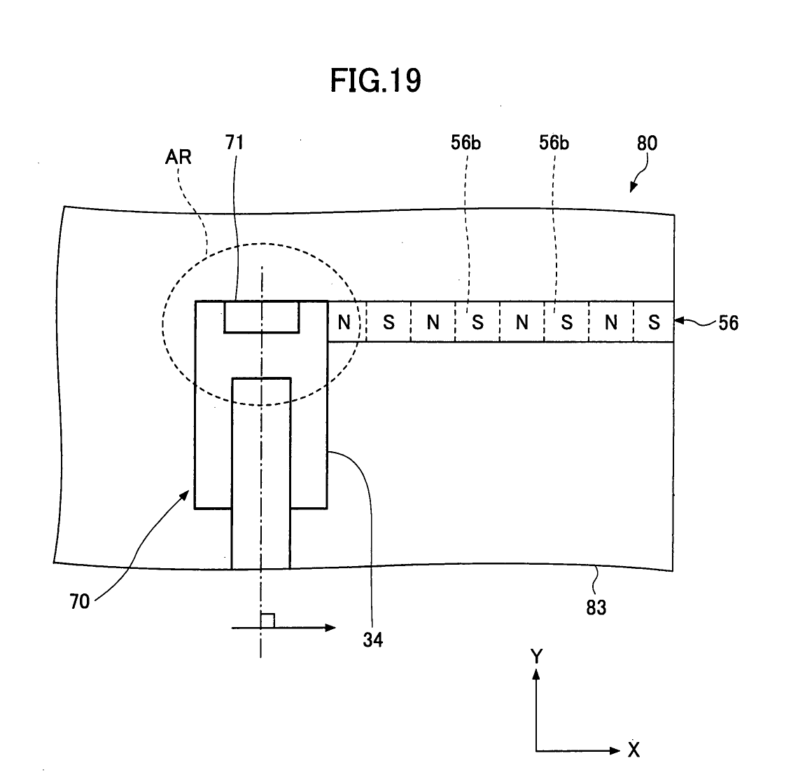

FIG. 19 is a figure for explaining recording processing in the method for measuring the magnetic field strength distribution of the magnetic head of the third embodiment. As shown in FIGS. 19 and 18, since the skew angle 7 is set to 90 degrees, the recording element longitudinal direction of the recording element 71 of the magnetic head is placed to be perpendicular to the move direction (X axis direction shown in FIG. 19) of the measurement medium. In this case, magnetized regions 56b are formed such that N-pole and S-pole (“N” and “S” in FIG. 19) alternately appear on the surface of the recording layer.

Next, in the same way as the track profile measurement processing (S110) shown in FIG. 4, track profiles are obtained by performing measurement by setting the skew angle of the reproduction head 60 to 0 degree. The reason is that the magnetization easy axis of the recording layer 83 of the measurement medium 80 is oriented to a direction perpendicular to the substrate plane.

Next, steps S104˜S114 shown in FIG. 4 are performed in the same way as the first embodiment, so that the recording magnetic field strength distribution is obtained by converting track profiles of each temperature to magnetic field strengths in step S116. The coercivity used in this step is a so-called perpendicular coercivity that is perpendicular to the substrate plane.

Accordingly, a recording magnetic field strength distribution, of the recording element longitudinal direction of the magnetic head, that is perpendicular to the substrate plane is obtained. Since the magnetic field strength distribution (not shown in the figure) of the recording element longitudinal direction can be obtained, a gradient of the magnetic field strength in the downstream side of the recording gap in the recording direction, and a magnetic field strength of a recording magnetic field in the downstream side in which the recording magnetic field direction is reversed can be obtained. By measuring the magnetic field strength distribution in the recording element longitudinal direction, it becomes possible to extract a magnetic head having a problem such as deterioration of non-linear transition shift (NLTS) characteristics or a problem of deleting a bit recorded by the recording element just after being recorded.

In addition, in the case of the magnetic head 70 for perpendicular magnetic recording, the main magnetic pole 70a of the magnetic head 70 becomes one magnetic pole and the soft magnetic lining layer of the magnetic recording medium (corresponding to the soft magnetic lining layer 82 of the measurement magnetic medium 80) becomes another magnetic pole, and recording characteristics are determined according to distribution of a recording magnetic field between these magnetic poles. In conventional technologies, for example, in the method described in the Description of the Related Art, the magnetic field strength distribution of the magnetic head for perpendicular magnetic recording cannot be measured accurately. However, according to the third embodiment, the medium for perpendicular magnetic recording is used as the measurement medium 80 and the measurement method in the first or second embodiment shown in FIG. 4 or 13 is used, so that the magnetic field strength distribution of recording magnetic field of the magnetic head 70 for perpendicular magnetic recording can be measured accurately.

The skew angle is not necessarily limited to 90 degrees. In addition, when the magnetic head 70 does not float stably, a stage such as a X stage or a X-Y stage that moves in one axis direction or two axis directions may be used instead of the rotation driving unit 18 of the measurement apparatus 10 shown in FIG. 1 so as to perform recording processing and track profile measurement processing while moving the measurement medium 80 shown in FIG. 18. Also according to this method, the recording magnetic field strength distribution for a perpendicular direction with respect to the substrate plane in the recording element longitudinal direction can be obtained.

### Fourth Embodiment

The method for measuring the magnetic field strength distribution of the magnetic head in the fourth embodiment is the same as that of the first to third embodiments except that the measurement method for the track profile is different.

In the fourth embodiment, when measuring the track profile in step S110 in FIG. 4 or 13, a magnetic force microscope (MFM) is used instead of the magnetic field detection element such as the reproduction element of the reproduction head or the magnetic head. By bringing a probe of the MFM close to the surface of the measurement medium and scanning the surface, the magnetic field strength distribution of the surface of the measurement medium can be obtained. As a result, a track profile similar to the track profile shown in FIGS. 9A˜9d can be obtained, for example.

In addition, in the recording processing (S110), the track profile may be measured by applying a recording magnetic field in which one reversal occurs in the recording direction and scanning the applied region by the MFM. Since sensitivity of the MFM is good and the scanning of the probe can be performed with high precision, the residual magnetization region of one reversal of recording magnetic field is adequate for performing measurement. Accordingly, the magnetic field strength distribution of the recording element width direction and the recording element longitudinal direction can be obtained.

In the recording processing (S110), a region having a residual magnetization whose size is almost the same as the size of the recording element may be formed on the measurement medium by stopping the measurement medium and supplying a pulse-like recording current to the magnetic head in a state the measurement medium is heated-up to a predetermined temperature. By scanning the region with the MFM, the magnetic field strength distribution of the surface of the measurement medium corresponding to the shape of the recording element can be obtained. Accordingly, the recording magnetic field strength distribution can be obtained in the same way as the first or second embodiment.

### Fifth Embodiment

In the method for manufacturing the magnetic head in the fifth embodiment of the present invention, methods for measuring the magnetic field strength distribution of the magnetic head in the first to fourth embodiments are applied to an inspection process for the magnetic head.

A manufacturing process of the magnetic head includes an element part forming process for forming a reproduction element and a recording element on a wafer, a floating plane forming process for forming a floating plane on a rover obtained by cutting out the wafer like a strip, an assembling process for cutting the rover to obtain each head slider and fixing the head slider to a suspension and the like, and the inspection process and the like.

First, with reference to FIG. 2, after assembling the suspension 31 and the head slider 34 of the magnetic head 11, the inspection process of the magnetic head 11 is performed. In the inspection process, it is determined whether a distribution of magnetic field strength generated from the recording element into which a predetermined recording current is supplied is within a range of a reference magnetic field strength distribution. When the distribution is within the range of the reference distribution, the magnetic head is determined to be a conforming item. If the distribution is not within the range of the reference distribution, the magnetic head is determined to be a nonconforming item and it is removed. In the following, a concrete inspection process is described.

For performing the inspection, the measurement apparatus 10 of the first embodiment shown in FIG. 1 is used. Steps S102˜S110 that are a part in the flowchart of FIG. 4 are performed. Then, by comparing a reference track profile of a predetermined range with the obtained track profile, it is determined whether the obtained track profile is within the range. In this inspection, since it is adequate to select the conforming item and the nonconforming item, it is adequate that the temperature for heating the measurement medium when performing recording is only one corresponding to a magnetic field strength that is the determination reference. Of course, all steps of the flowchart of FIG. 4 may be performed so that the recording magnetic field strength distribution in the recording element width direction shown in FIG. 11, for example, may be obtained so as to determine whether the obtained distribution is within the range of the reference magnetic field strength distributions. Further, all steps of the flowchart of FIG. 13 may be performed so that the recording magnetic field strength distribution for the whole recording element shown in FIG. 16 may be obtained, so that it may be determined whether the obtained distribution is within the range of the reference magnetic field strength distribution.

According to the manufacturing method of the fifth embodiment, since it is determined whether the magnetic head is a conforming item by measuring the magnetic field strength distribution directly or indirectly using a simple method, reliable magnetic heads can be manufactured.

The present invention is not limited to the specifically disclosed embodiments, and variations and modifications may be made without departing from the scope of the present invention.

For example, a longitudinal magnetic recording medium is used as the measurement medium and a horizontal magnetic field strength distribution of the magnetic head for longitudinal magnetic recording is measured in the first and second embodiments. Instead of that, a perpendicular magnetic field strength distribution of the magnetic head can be measured using the measurement medium 80 for perpendicular magnetic recording. In addition, a perpendicular magnetic field strength distribution of the magnetic head 70 for perpendicular magnetic recording is measured using a perpendicular magnetic recording medium as the measurement medium 80 shown in FIG. 18 in the third embodiment. Instead of that, a horizontal magnetic field strength distribution of the magnetic head for perpendicular magnetic recording may be measured using the measurement medium 50 for longitudinal magnetic recording shown in FIG. 5. Further, by using an obliquely oriented (tilted) medium as the measurement medium, a slanting magnetic field strength distribution of the magnetic head can be measured.

In addition, in the measurement methods of the first to fourth embodiments, recording may be performed for each temperature while a bias magnetic field (direct current magnetic field) is applied along one direction among recording magnetic field applying directions. The direction in which the bias magnetic field is applied is parallel to the substrate plane and is parallel to the recording element longitudinal direction when the measurement medium is the longitudinal magnetic recording medium. When the measurement medium is the perpendicular magnetic recording medium, the direction is perpendicular to the substrate plane. Accordingly, since the magnetic field strength is increased by the bias magnetic field compared with the recording magnetic field generated from the magnetic head, residual magnetization can be formed without heating the measurement medium to a high temperature. In this case, the magnetic field strength of the magnetic head is a magnetic field strength obtained by subtracting the magnetic field strength of the bias magnetic field.

In addition, in the measurement apparatus 10 in FIG. 1, the recording processing and measurement of the track profile are performed by rotating the measurement medium 50 using the rotation driving unit 18 so as to float the magnetic head 11 and the reproduction head 60. Alternatively, a stage such as a X stage or a X-Y stage that moves in one axis direction or two axis directions may be used instead of the rotation driving unit 18. In this case, the measurement medium is loaded on the stage, and the stage is moved so that the recording processing and measurement of the track profile are performed in the same way as the first to third embodiments. In addition, instead of moving the measurement medium when measuring the track profile, the reproducing head may be simply moved in the track width direction. In this case, although the magnetic head 11 and the reproduction head 60 contact the surface of the measurement medium, measurement of the magnetic field strength distribution is not affected by this.

The present application contains subject matter related to Japanese patent application No. 2005-315233, filed in the JPO on Oct. 28, 2005, the entire contents of which are incorporated herein by reference.

What is claimed is:

1. A method for measuring a recording magnetic field strength distribution of a magnetic head, the method comprising:
a first step of setting the magnetic head to a predetermined skew angle, and magnetically forming a track on a measurement magnetic recording medium using the magnetic head in a state in which the measurement magnetic recording medium is heated to a predetermined temperature;
a second step of measuring a track profile of the track by a magnetic field detection element;
a third step of repeating the first step and the second step in which temperatures for heating the measurement magnetic recording medium in repeating the first step are different with each other; and
a fourth step of converting track profiles obtained in the third step into a recording magnetic field strength distribution.

2. The method as claimed in claim 1, wherein a region on which recording is performed for the track by the magnetic head is heated by irradiating the region with laser light in the first step.

3. The method as claimed in claim 2, wherein the measurement magnetic recording medium comprises a transparent substrate and a recording layer formed on one surface of the transparent substrate; and
wherein the region is irradiated with the laser light from another surface opposite to the surface on which the recording layer is formed in the first step.

4. The method as claimed in claim 1, wherein coercivity of the measurement magnetic recording medium at the lowest temperature at which a peak appears in a track profile is determined to be a recording magnetic field strength in the fourth step.

5. The method as claimed in claim 1, wherein coercivity of the measurement magnetic recording medium at a temperature at which a peak is saturated in the track profiles is determined to be a recording magnetic field strength in the fourth step.

6. A method for measuring a recording magnetic field strength distribution of a magnetic head, the method comprising:
a first step of setting the magnetic head to a predetermined skew angle, and magnetically forming a track on a measurement magnetic recording medium using the magnetic head in a state in which the measurement magnetic recording medium is heated to a predetermined temperature;
a second step of measuring a track profile of the track by a magnetic field detection element;
a third step of repeating the first step and the second step in which temperatures for heating the measurement magnetic recording medium in repeating the first step are different with each other; and
a fourth step of repeating the third step in which skew angles in repeating the first step are different with each other and are within a predetermined range; and
a fifth step of converting track profiles obtained in the fourth step into a recording magnetic field strength distribution.

7. The method as claimed in claim 6, wherein a region on which recording is performed for the track by the magnetic head is heated by irradiating the region with laser light in the first step.

8. The method as claimed in claim 7, wherein the measurement magnetic recording medium comprises a transparent substrate and a recording layer formed on one surface of the transparent substrate; and
wherein the region is irradiated with the laser light from another surface opposite to the surface on which the recording layer is formed in the first step.

9. The method as claimed in claim 6, wherein coercivity of the measurement magnetic recording medium at the lowest temperature at which a peak appears in a track profile is determined to be a recording magnetic field strength in the fifth step.

10. The method as claimed in claim 6, wherein coercivity of the measurement magnetic recording medium at a temperature at which a peak is saturated in the track profiles is determined to be a recording magnetic field strength in the fifth step.

11. A method for measuring a recording magnetic field strength distribution of a magnetic head, the method comprising:
a first step of setting the magnetic head to a predetermined skew angle, and magnetically forming a track on a measurement magnetic recording medium using the magnetic head in a state in which the measurement magnetic recording medium is heated to a predetermined temperature;
a second step of measuring a track profile of the track by a magnetic field detection element; and
a third step of identifying a position at which a recording magnetic field equal to or greater than coercivity of the measurement magnetic recording medium at the predetermined temperature is generated.

12. The method as claimed in claim 1, wherein a recording layer of the measurement magnetic recording medium comprises a ferromagnetic material including Co and Pt.

13. The method as claimed in claim 12, wherein an axis of easy magnetization of the recording layer is oriented to be almost perpendicular to a film surface of the recording layer, and a recording magnetic field strength distribution of a perpendicular direction is obtained for the magnetic head.

14. The method as claimed in claim 12, wherein an axis of easy magnetization of the recording layer is oriented to be almost parallel to a film surface of the recording layer, and a recording magnetic field strength distribution of in-plane direction is obtained for the magnetic head.

15. The method as claimed in claim 1, wherein the magnetic detection element is one of a magnetoresistive element, a tunnel magnetoresistive element and a probe element.

16. A method for manufacturing a magnetic head, the method comprising an inspection process, the inspection process comprising:
a first step of setting the magnetic head to a predetermined skew angle, and magnetically forming a track on a measurement magnetic recording medium using the magnetic head in a state in which the measurement magnetic recording medium is heated to a predetermined temperature;
a second step of measuring a track profile of the track by a magnetic field detection element;
a third step of identifying a position at which a recording magnetic field equal to or greater than coercivity of the measurement magnetic recording medium at the predetermined temperature is generated; and
a fourth step of comparing the position at which the recording magnetic field is generated with a reference position at which a recording magnetic field is generated, and determining the magnetic head to be an conforming item when the positions are the same.

17. A measurement apparatus for measuring a recording magnetic field strength distribution of a magnetic head, comprising:
a magnetic head position determination unit;
a heating unit configured to heat a measurement magnetic recording medium;
a recording unit configured to form a track on the measurement magnetic recording medium using the magnetic head in a state in which the measurement magnetic recording medium is heated to a predetermined temperature by the heating unit;
a track profile measurement unit configured to measure a track profile of the track using a magnetic field detection element; and
a calculation unit configured to identify a position at which a recording magnetic field equal to or greater than coercivity of the measurement magnetic recording medium at the predetermined temperature is generated.

18. The measurement apparatus as claimed in claim 17, the measurement apparatus further comprising:
a rotation driving unit configured to rotate the measurement magnetic recording medium that is a disk;
wherein the heating unit is configured to irradiate the measurement magnetic recording medium with laser light.

19. A measurement magnetic recording medium including a substrate and a recording layer formed on the substrate,
wherein the measurement magnetic recording medium is used in a method for measuring a recording magnetic field strength distribution of a magnetic head, the method comprising:
a first step of setting the magnetic head to a predetermined skew angle, and magnetically forming a track on the measurement magnetic recording medium using the magnetic head in a state in which the measurement magnetic recording medium is heated to a predetermined temperature;
a second step of measuring a track profile of the track by a magnetic field detection element;
a third step of repeating the first step and the second step in which temperatures for heating the measurement magnetic recording medium in repeating the first step are different with each other; and
a fourth step of converting track profiles obtained in the third step into a recording magnetic field strength distribution.

20. A measurement magnetic recording medium including a substrate and a recording layer formed on the substrate,
wherein the measurement magnetic recording medium is used in a method for measuring a recording magnetic field strength distribution of a magnetic head, the method comprising:
a first step of setting the magnetic head to a predetermined skew angle, and magnetically forming a track on the measurement magnetic recording medium using the magnetic head in a state in which the measurement magnetic recording medium is heated to a predetermined temperature;
a second step of measuring a track profile of the track by a magnetic field detection element;
a third step of repeating the first step and the second step in which temperatures for heating the measurement magnetic recording medium in repeating the first step are different with each other;
a fourth step of repeating the third step in which skew angles in repeating the first step are different with each other; and
a fifth step of converting track profiles obtained in the fourth step into a recording magnetic field strength distribution.

21. A measurement magnetic recording medium including a substrate and a recording layer formed on the substrate,
wherein the measurement magnetic recording medium is used in a method for measuring a recording magnetic field strength distribution of a magnetic head, the method comprising:
a first step of setting the magnetic head to a predetermined skew angle, and magnetically forming a track on the measurement magnetic recording medium using the magnetic head in a state in which the measurement magnetic recording medium is heated to a predetermined temperature;
a second step of measuring a track profile of the track by a magnetic field detection element; and
a third step of identifying a position at which a recording magnetic field equal to or greater than coercivity of the measurement magnetic recording medium at the predetermined temperature is generated.

22. The measurement magnetic recording medium as claimed in any one of claims 19-21, wherein relationship between coercivity and temperature of the recording layer is substantially linear in a predetermined temperature range at which the recording magnetic field strength distribution is measured.

23. The measurement magnetic recording medium as claimed in any one of claims 19-21, wherein the coercivity of the recording layer is greater than the maximum magnetic field strength of the magnetic head in a lower side temperature in a predetermined temperature range.

24. The measurement magnetic recording medium as claimed in any one of claims 19-21, wherein an axis of easy magnetization of the recording layer is oriented to almost one direction.
